(19) United States
(12) Patent Application Publication
(10) Pub. No.: US 2008/0048245 A1
(43) Pub. Date: Feb. 28, 2008

(54) Semiconductor device and manufacturing methods thereof

(76) Inventors: Masaru Kito, Yokohama-shi (JP); Hideaki Aochi, Kawasaki-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/889,863

(22) Filed: Aug. 17, 2007

(30) Foreign Application Priority Data
Aug. 23, 2006 (JP) 2006-227211

(51) Int. Cl. H01L 29/04; H01L 21/336; H01L 27/115

(52) U.S. Cl. 257/321; 438/268; 257/E27.103; 257/E29.003; 257/E21.41

(57) ABSTRACT

A semiconductor device includes: a substrate having a main surface, a first main electrode formed on the main surface of the substrate, a pillar shaped semiconductor layer formed on the first main electrode and having poly crystal, a second main electrode formed on the pillar shaped semiconductor layer, an insulation layer formed on the side of the pillar shaped semiconductor layer, a control electrode formed on the side of the pillar shaped semiconductor layer interposed by said insulation layer and, a tunnel insulation layer which intersects a main current pathway in the pillar shaped semiconductor layer.

### CROSS REFERENCE TO RELATED APPLICATION

This application is based upon and claims the benefit of priority from the prior Japanese Patent Applications No. 2006-227211, filed on Aug. 23, 2006; the entire contents of which are incorporated herein by reference.

### BACKGROUND OF THE INVENTION

1. Field of the Invention

This invention is related to a semiconductor device and its manufacturing methods and in particular it is related to a semiconductor device which has a vertical type transistor and its manufacturing methods thereof.

2. Description of the Related Art

A semiconductor device which has a vertical type transistor is well known. For example, in the Patent Laid-Out Publication No. 2002-83945, a usage method in the field of non-volatile memory such as dynamic type random access memory (DRAM) or flash memory (EEPROM) is proposed.

The vertical type transistor is provided with a pillar shaped semiconductor layer used as a channel forming region, a source diffusion region and a drain diffusion region which are each formed in the upper and lower ends of this semiconductor layer, a source electrode formed in the source diffusion region, a drain electrode formed in the drain diffusion region, a gate insulation layer which is formed surrounding this semiconductor layer on the side of the center part of the semiconductor layer and a gate electrode on the gate insulation layer.

The following 2 types of formation methods are usual among the formation methods of a pillar shaped semiconductor layer. One formation method forms a semiconductor layer using single/mono crystalline silicon by epitaxial growth. The other formation method adds heat to a non crystalline silicon, forms a polycrystalline silicon and forms a semiconductor layer by this polycrystalline silicon.

In the semiconductor layer in which a film is formed on the semiconductor substrate, a polycrystalline silicon which can be easily manufactured, is used. Within the pillar shaped semiconductor layer which is formed from this polycrystalline silicon, several grains are produced and it is difficult to control the amount and orientation of these grains by a manufacturing process. Between each grain there exists a grain boundary and it is easy for impurity atoms which control the resistance value of the semiconductor layer, to accumulate on this grain boundary.

Between the drain diffusion region and the source diffusion region of this type of vertical transistor, a phenomenon whereby the grain boundaries of the semiconductor layer are connected in series occurs frequently. In this case, through the grain boundaries which are connected in series, the source diffusion region and the drain diffusion region becomes electrically connected. In other words, when the vertical transistor operation is cut off electric current leaks between the source diffusion region and the drain diffusion region via the grains boundaries and cut off current increases.

### BRIEF SUMMARY OF THE INVENTION

A first aspect relating to an embodiment of this invention is a semiconductor device including:

a substrate having a main surface;

a first main electrode formed on the main surface of the substrate;

a pillar shaped semiconductor layer having poly crystal formed on the first main electrode;

a second main electrode formed on the pillar shaped semiconductor layer;

an insulation layer formed on the side of the pillar shaped semiconductor layer;

a control electrode formed on the side of the pillar shaped semiconductor layer interposed by the insulation layer and;

a tunnel insulation layer which intersects a main current pathway in the pillar shaped semiconductor layer.

A second aspect relating to an embodiment of this invention is a semiconductor device including:

a substrate having a main surface;

a first main electrode formed on the main surface of the substrate;

a first pillar shaped semiconductor layer formed on the first main electrode and having poly crystal;

a second main electrode formed on the first pillar shaped semiconductor layer;

a first insulation layer formed on the side of the first pillar shaped semiconductor layer and;

a first transistor having a first control electrode formed on the side of the first pillar shaped semiconductor layer interposed by the first insulation layer;

a third main electrode formed on the first transistor;

a second pillar shaped semiconductor formed on the third main electrode and having poly crystal;

a fourth main electrode formed on the second pillar shaped semiconductor;

a second insulation layer formed on the side of the second pillar shaped semiconductor and having a charge accumulating region and;

a second transistor having a second control electrode formed on the side of the second pillar shaped semiconductor layer interposed by the second insulation layer;

a fifth main electrode formed on the second transistor;

a third pillar shaped semiconductor layer formed on the fifth main electrode and having a poly crystal;

a sixth main electrode formed on the third pillar shaped semiconductor layer;

a third insulation layer formed on the side of the third pillar shaped semiconductor layer and;

a third transistor having a third control electrode formed on the side of the third pillar shaped semiconductor layer interposed by the third insulation layer and;

a tunnel insulation layer which intersects a main current pathway in either a first pillar shaped semiconductor of a first transistor, a second pillar shaped semiconductor of a second transistor or a third pillar shaped semiconductor of a third transistor.

A third aspect relating to an embodiment of this invention is a method for manufacturing a semiconductor device comprising;

forming a first main electrode on the main surface of a substrate;

forming one part of a pillar shaped semiconductor layer on the first main electrode;

forming a tunnel insulation layer on the surface of one part of the pillar shaped semiconductor layer;

forming another part of the pillar shaped semiconductor layer on the tunnel insulation layer and forming a pillar shaped semiconductor layer interposed by one part and another part and having poly crystal;

forming an insulation layer on the side of the pillar shaped semiconductor layer and;

forming a control electrode on the side of the pillar shaped semiconductor interposed by the insulation layer.

### BRIEF DESCRIPTION OF THE DRAWINGS

FIG. 1 is an enlarged cross section view of the required parts of a vertical type transistor which is mounted on a semiconductor device relating to a first embodiment of this invention.

FIG. 2 is a cross section view showing a plurality of vertical type transistors in a semiconductor device.

FIG. 3 is a first process cross section view which explains a manufacturing method of a semiconductor device shown in FIG. 1.

FIG. 4 is a second process cross section view.

FIG. 5 is a third process cross section view.

FIG. 6 is a fourth process cross section view.

FIG. 7 is a fifth process cross section view.

FIG. 8 is a sixth process cross section view.

FIG. 9 is a circuit diagram of a memory cell array of a NOR type flash memory relating to a second embodiment of this invention.

FIG. 10 is a cross section view (the cross section view cut by the section line F10-F10 shown in FIG. 16) of a memory cell array relating to a second embodiment of this invention.

FIG. 11 is a cross section view (the cross section view cut by the section line F11-F11 shown in FIG. 16) of a memory cell array relating to a second embodiment of this invention

FIG. 12 is a horizontal plane view of a memory cell array relating to a second embodiment.

FIG. 13 is a circuit diagram of a memory cell array of a NAND type flash memory relating to a third embodiment of this invention.

FIG. 14 is a cross section view (the cross section view cut by the section line F14-F14 shown in FIG. 16) of a memory cell array relating to a third embodiment of this invention.

FIG. 15 is a cross section view (the cross section view cut by the section line F15-F15 shown in FIG. 16) of a memory cell array relating to a third embodiment of this invention.

FIG. 16 is a horizontal plane view of a memory cell array relating to third embodiment.

FIG. 17 is a first process cross section view which explains a manufacturing method of a NAND type flash memory shown in FIG. 14 and FIG. 15.

FIG. 18 is a second process cross section view.

FIG. 19 is a third process cross section view.

FIG. 20 is a fourth process cross section view.

FIG. 21 is a fifth process cross section view.

FIG. 22 is a sixth process cross section view.

FIG. 23 is a seventh process cross section view.

FIG. 24 is an eighth process cross section view.

FIG. 25 is a ninth process cross section view.

FIG. 26 is a first process cross section view which explains a manufacturing method of a semiconductor device relating to a fourth embodiment of this invention.

FIG. 27 is a second process cross section view.

FIG. 28 is a third process cross section view.

FIG. 29 is a fourth process cross section view.

FIG. 30 is a fifth process cross section view.

FIG. 31 is a sixth process cross section view.

FIG. 32 is a seventh process cross section view.

FIG. 33 is an eighth process cross section view.

FIG. 34 is a ninth process cross section view.

FIG. 35 is a cross section view of a memory cell array of a NAND type flash memory relating to a fifth embodiment of this invention.

### DETAILED DESCRIPTION OF THE INVENTION

Below, the preferred embodiments of the present invention will be explained in detail while referring to the drawings. However, the examples are possible in many different embodiments and are not limited to the details cited in the embodiments shown below. In addition, in several embodiments, the same symbols have been used for construction components which have the same function and therefore an explanation of those that are repeated is omitted.

### First Embodiment

In a first embodiment one of the present invention, an example which applies the present invention to a semiconductor device including a transistor having a vertical type construction, is explained. In particular, the transistor in embodiment one constructs a logic circuit which is mounted on a semiconductor device.

[Construction of a Transistor Mounted on a Semiconductor Device]

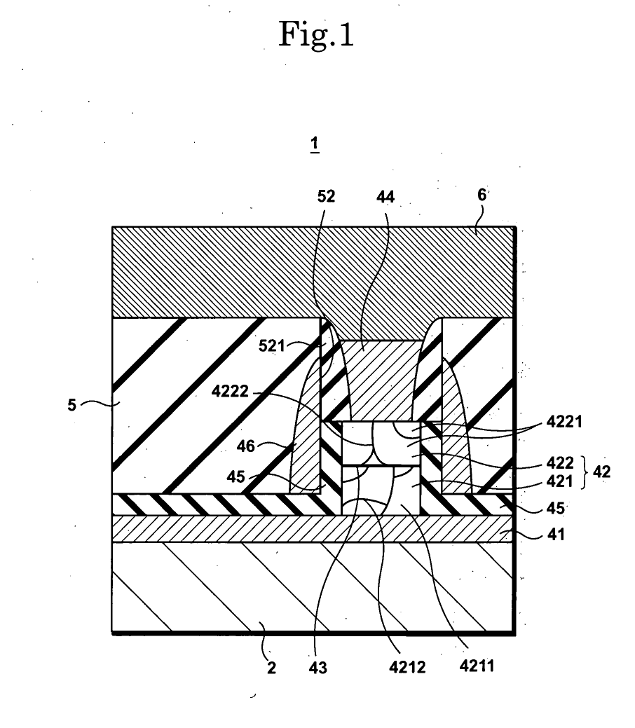

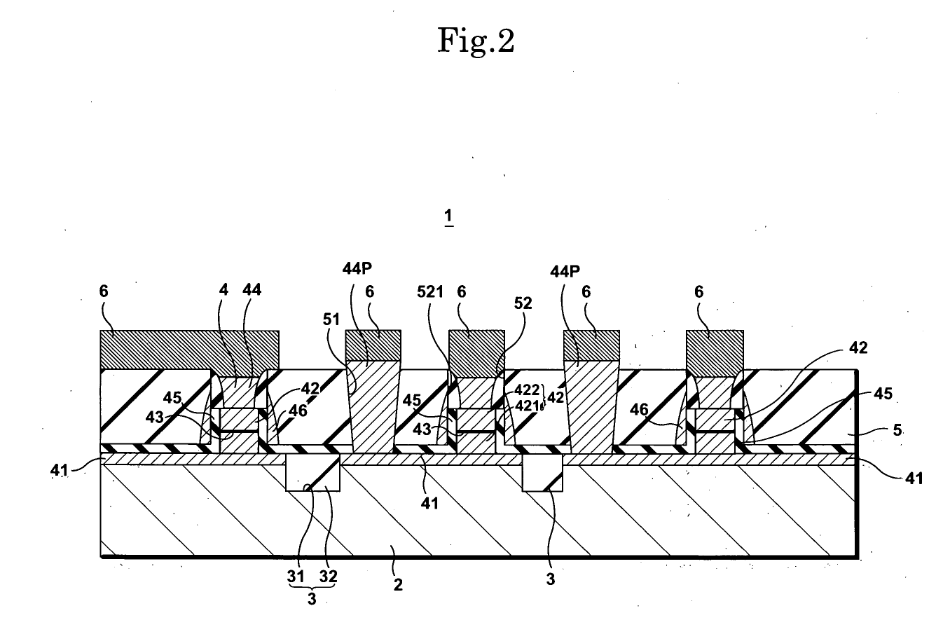

As shown in FIG. 1 and FIG. 2, the semiconductor device relating to the first embodiment of this invention comprises a substrate 2 on a main body. A silicon single crystal substrate is used, for example, in the substrate 2. A transistor 4 is mounted in an area where the circumference is surrounded by an isolation area 3 on the main surface (here, element forming surface) of this substrate 2. In the first embodiment, the transistor 4 is an n channel conduction type IGFET (insulating gate type field effect transistor) which has a vertical type construction. Here, the IGFET includes at least a MOSFET (metal oxide semiconductor field effect transistor) and a MISFET (metal insulator semiconductor field effect transistor). In addition, a vertical type construction means a construction of a transistor wherein a current flows in a vertical direction and in the first embodiment in a direction which intersects the main face of substrate 2. Since the transistor 4 in the first embodiment is comprised by an n channel conduction type IGFET, it is possible to use a p type silicon single crystal substrate or a p type or an n type silicon single crystal substrate which has a p type well region in the substrate 2.

The isolation area 3 is formed by an STI (shallow trench isolation) construction. That is, the isolation area 3 is arranged with a trench 31 which is formed in that depth direction from the main face of substrate 2 and an insulator 31 which is deposited within this trench 31. The trench 31 is formed by anisotropic etching such as the RIE (reactive ion etching) method and a silicon oxide film is used in the insulator 31. Furthermore, the isolation area 3 can also be constructed by a field oxide film which is formed by selectively oxidizing the main surface of substrate 2.

The transistor 4 is arranged with a first main electrode 41 which is formed on the main surface of the substrate 2 and a pillar shaped semiconductor layer 42 including poly crystal, formed above the first main electrode 41, a second main electrode 44 which is formed above the pillar shaped semiconductor layer 42, an insulation layer 45 which is formed on the side of the pillar shaped semiconductor layer 42, a control electrode 46 which is formed interposed by the insulation layer 45 on the side of the pillar shaped semiconductor layer 42 and a tunnel insulation layer 43 which intersects a main current pathway in the pillar shaped semiconductor layer 42.

The first main electrode 41 of the transistor 4 is formed in detail by the semiconductor region which is formed by introducing impurities in a depth direction from the surface of the substrate 2. Here, the introduction of impurities includes the introduction of impurities by an ion implantation method, by a solid-phase diffusion method or by a combination of both of these methods. The first main electrode 41 is used, for example, as a source electrode (or a drain electrode) of the transistor 4. The first main electrode 41 is basically in contact with the bottom surface of the pillar shaped semiconductor layer 42 and can be arranged in an area equivalent to this bottom surface of the pillar shaped semiconductor layer 42, however, because a main current is taken out from the main surface side of the substrate 2, it is extracted as far as the exterior of the pillar shaped semiconductor 42. The bottom surface of a plug wire 44P which is laid in a connection hole 51 which is arranged in an interlayer insulation film 5 is electrically connected to the area of the first main electrode 41 which is extracted, as shown in FIG. 2. A wire 6 which is arranged on the interlayer insulation film 5 is electrically connected to the upper surface of the plug wire 51. Furthermore, the first main electrode 41 in the first embodiment is arranged on the main surface (surface part) of the substrate 2, however, a semiconductor layer (a silicon single crystal layer or a silicon poly crystal layer) can be further arranged on the main surface of the substrate 2.

The pillar shaped semiconductor layer 42 is used as a channel forming region and is arranged with a first semiconductor layer 421 and a second semiconductor layer 422. The first semiconductor layer 421 is arranged in the lower part of the pillar shaped semiconductor layer 42 and is electrically connected to the first main electrode 41. The second semiconductor layer 422 is arranged above the first semiconductor layer 421. The second semiconductor layer 422 is electrically connected to the second main electrode 44. The tunnel insulation layer 43 is arranged between the first semiconductor layer 421 and the second semiconductor layer 422. In other words, the pillar shaped semiconductor 42 is separated into a first semiconductor layer 421 and a second semiconductor layer 422 interposed by the tunnel insulation layer 43. The first semiconductor layer 421 and the second semiconductor layer 422 are as a final product both poly crystal regardless of the production process. In other words, the first semiconductor layer 421 and the second semiconductor layer 422 include the case where they are first formed into a layer by an amorphous substance and later changed into poly crystal or when they are formed from start to finish by poly crystal. Because it is possible to easily control the resistance value and the diameter of the grain boundary etc in the production process of a semiconductor device 1 according to the first embodiment, amorphous silicon is formed into a layer and at an appropriate stage the amorphous silicon is modified into a poly crystal.

As shown in FIG. 1, a plurality of grains 4211 exist in the first semiconductor layer 421 of the pillar shaped semiconductor layer 42 and between the grain 4211 and another grain 4211 which adjoins it there is a grain boundary 4212. Similarly, there exists a plurality of grains 4221 in the second semiconductor layer 422 and between a grain 4221 and another grain 4221 which adjoins it there is a grain boundary 4222. In the first embodiment, both the first semiconductor layer 421 and the second semiconductor layer 422 of the pillar shaped semiconductor 43 are formed from a silicon poly crystal film. The conductive type impurities of a p type, n type or both which control the threshold voltage of a transistor 4, are introduced into this silicon poly crystal film.

The tunnel insulation layer 43 is arranged in the central part of the pillar shaped semiconductor layer 42. The layer surface of the tunnel insulation layer 43 is made to horizontally face the main surface of the substrate 2. In other words, the layer surface of the tunnel insulation layer 43 is effectively arranged in parallel on either the bottom surface or upper surface of the pillar shaped semiconductor layer 42. The tunnel insulation layer 43 is connected to the top surface and bottom surface of the pillar shaped semiconductor 42, that is, the continuity of the grain boundaries 4212 and 4222 which are connected from the first main electrode 41 to the second main electrode are intersected. That is, when the transistor 4 is OFF, the tunnel insulation layer 43 intersects a leak current which flows through the grain boundaries 4212 and 4222 between the first main electrode 41 and the second main electrode 44. Furthermore, when the transistor 4 is ON, the tunnel insulation layer 43 passes a main current between the first main electrode 41 and the second main electrode 44 interposed by a tunnel phenomenon.

The tunnel insulation layer 43 is comprised of a silicon oxide film in the first embodiment. Specifically, the layer thickness of the tunnel insulation layer 43 is more than/above 0.6 nm, which is the same layer thickness as a natural oxide layer and is set at 2.0 nm. If it is not arranged with a layer thickness of more than 0.6 nm the tunnel insulation layer 43 can not intersect a leak current. Alternatively, if it is not arranged with a layer thickness of less than 2.0 nm the tunnel insulation layer 43 can not allow a main current to flow by the tunnel phenomenon. For practical purposes, the layer thickness of the tunnel insulation layer 43 is set within the range of 0.6 nm and 2.0 nm. Furthermore, in the first embodiment, the tunnel insulation layer 43 is arranged in one place which intersects a main current pathway of the pillar shaped semiconductor layer 42. However, the present invention is not limited to this. In other words, in the present invention it is possible to set the tunnel insulation layer 43 in a plurality of at least 2 or more places which intersect a main current pathway in the pillar shaped semiconductor layer 42. That is, it is possible to arrange a plurality of at least two or more tunnel insulation layers 43 in the pillar shaped semiconductor according to the present invention. Also, the tunnel insulation layer 43 can be formed by a silicon nitride film. Also, in the first embodiment, the tunnel insulation layer 43 is arranged in the central part of the pillar shaped semiconductor layer 42, however, because the grain boundaries 4212 and 4222 which are connected between the first main electrode 41 and the second main electrode 44, are intersected, it is possible to arrange the tunnel insulation layer 43 in a position which is close to the first main electrode 41 compared to the center of the pillar shaped semiconductor layer 42 or it is possible to arrange the tunnel insulation layer 43 in a position which is close to the second main electrode 44 compared to the center of the pillar shaped semiconductor layer 42.

The second main electrode 44 is interposed by a spacer 521 and laid in an opening 52 which is arranged on the pillar shaped semiconductor layer 42 of the interlayer insulation layer 5 which is laid in the pillar shaped semiconductor 42. The second main electrode 44 is, for example, used as a drain electrode (or a source electrode) of the transistor 4. The spacer 521 is arranged on and self aligned with the inner wall of the opening 52 of the interlayer insulation film 5 and electrically separates the second main electrode 44 and the control electrode 46. If the second main electrode 44 and the control electrode 46 are completely and electrically insulated then there is not always a need for the spacer 521. The second main electrode 44 is exposed in the area whose outer side is surrounded by the bottom surface of the spacer 521 of the opening 52 and contacts with and is electrically connected to the upper surface of the pillar shaped semiconductor layer 42, or more specifically, to the upper surface of the second semiconductor layer 422. It is possible to practically use a single layer of either a silicon poly crystal, refractory metal or a refractory metal silicide or a composite layer which has accumulated layers of a gate electrode material on a barrier metal layer as a gate electrode material which can sustain a high temperature treatment in the manufacturing process of the semiconductor device 1 in the second main electrode 44. Impurities which adjust a resistance value are injected into the silicon poly crystal.

An insulation layer 45 is the gate insulation layer of the transistor 4. The insulation layer 45 is arranged on the side of the pillar shaped semiconductor layer 42. It is possible to practically use a single layer of either a silicon oxide layer, a silicon nitride layer or an oxy-nitride layer or a compound membrane layer which overlaps those two or more varieties. The insulation layer 45 has layer thickness which is thicker than the layer thickness of tunnel insulation layer 43 in the first embodiment. This layer thickness of the insulation layer 45 is set at 2 nm-15 nm, for example, when formed by a silicon oxide layer.

The control electrode 46 is the gate electrode of the transistor 4. The control electrode 46 is interposed by the insulation layer 45 and arranged on the side of the pillar shaped semiconductor layer 42. It is possible to practically use a single layer of either a silicon poly crystal, refractory metal or a refractory metal silicide or a compound membrane layer which has accumulated layers of a refractory metal layer or a refractory metal silicide on a layer of silicon poly crystal. The control electrode 46 is formed by self alignment with this pillar shaped semiconductor layer 42 on the side of the pillar shaped semiconductor layer 42.

A wire 6 is arranged on the interlayer insulation layer 5. The wire 6 is electrically connected to the second main electrode 44 of the transistor 4 or a plug wire 44P. It is possible to practically use a single layer of either silicon poly crystal, refractory metal, refractory metal silicide or a low resistance metal or a compound membrane layer which has accumulated 2 or more of these varieties. Here, at least an aluminum alloy, Cu or Cu alloy which is at least added in to one additive of either Si or Cu is included in the low resistance metal.

[Transistor Switch Operation]

Cut-Off Operation

In the cut-off operation of the transistor 4 which is comprised by an n channel conductive type IGFET a low level signal is input to the control electrode 46. Based on the input of this control signal a depletion layer is produced in the pillar shaped semiconductor layer 42. Grain boundaries 4212 and 4222 exist between the first main electrode 41 and the second main electrode 44 in the pillar shaped semiconductor 42. Because the tunnel insulation layer 43 is arranged in the pillar shaped semiconductor layer 42 in the transistor 4 relating to the first embodiment, the connection between the grain boundaries 4212 and 4222 is severed. Therefore, it is possible to prevent a generation of current leak which interposes impurities which are easily trapped in the grain boundaries 4212 and 4222.

ON Operation

On the other hand, in the ON operation of the transistor 4, a control electrode 46 is input with a high level control signal. Based on this input control signal a channel region is produced in the side surface region of the pillar shaped semiconductor layer 42. If the voltage of the second main electrode 44 is high (for example, a power charge voltage of 2.5 V-5.0 V) against the voltage of the first main electrode 41 (for example, a standard voltage of 0 V) electrons flow from the first main electrode 41 to the first semiconductor layer 421 of the pillar shaped semiconductor layer 42 and these electrons pass through the tunnel insulation layer 43 interposed by the tunnel phenomenon and the electrons which pass through flow to the second main electrode 44 interposed by the second semiconductor layer 422.

[Manufacturing Method of the Semiconductor Device]

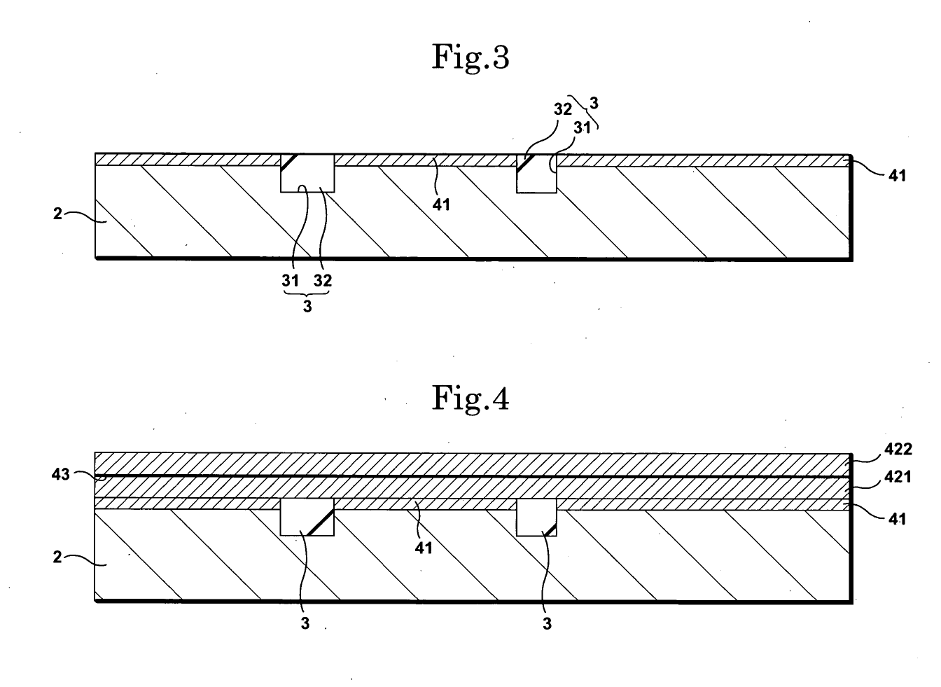

Next, a manufacturing method of the previously stated semiconductor device 1 will be explained using FIG. 3 to FIG. 8. Firstly, a substrate 2 is prepared. An isolation area 3 is formed in a non active area on the main surface of this substrate 2 (See FIG. 3). A trench 31 is formed by etching to a depth from the main surface of the substrate 2 using RIE and The isolation area 3 is formed by laying an insulation object 32 within this trench 31.

As is shown in FIG. 3, on the main surface of the substrate 2 The first main electrode 41 (including the area which has been extracted) is formed in the active area of the region which is surrounded by the non active area. N type impurities are introduced to the main surface part of the substrate 2 using an Ion implantation method and the first main electrode 41 is formed by activating these n type impurities. It is possible to use, for example, at least one of either arsenic (As), or phosphorus (P) in the n type impurities. In addition, it is also possible to use a solid phase diffusion method in the introduction of the n type impurities.

As is shown in FIG. 4, the first semiconductor 421, the tunnel insulation layer 43 and the second semiconductor layer 422 are respectively accumulated in order on the first main electrode 41 and on the entire surface on the main surface of the substrate 2 which includes the isolation area 3. This first semiconductor layer 421, the tunnel insulation layer 43 and the second semiconductor layer 422 form the pillar shaped semiconductor layer 42. The first semiconductor layer 421 is formed by a silicon amorphous layer which has been formed by a CVD (chemical vapor deposition) method and the layer thickness of the first semiconductor layer 421 is set at 75 nm for example. The tunnel insulation layer 43 is formed by a silicon oxide layer which is formed by oxidizing the surface of the first semiconductor layer 421 at a low temperature. The tunnel insulation layer 43 is formed at low temperature of around 450 degrees Celsius, for example, and the layer thickness of the tunnel insulation layer 43 is between 0.6 nm and 2.0 nm and in the first embodiment is set between 0.8 nm and 1.0 nm. The silicon oxide layer formed by oxidization can obtain a fine layer material. Furthermore, it is possible to form the tunnel insulation layer 43 by the silicon oxide layer or silicon nitride layer deposited by a CVD method or a spattering method. The second semiconductor layer 422 is formed in the same way as the first semiconductor layer 421 by a silicon amorphous layer which is formed by a CVD method and the layer thickness of the second semiconductor layer 422 is set, for example, at 75 nm. In the first embodiment, the first semiconductor layer 421 and the second semiconductor layer 422 are both formed by a silicon amorphous layer and it is possible to improve the diffusion control regulation of the impurities which control a resistance value.

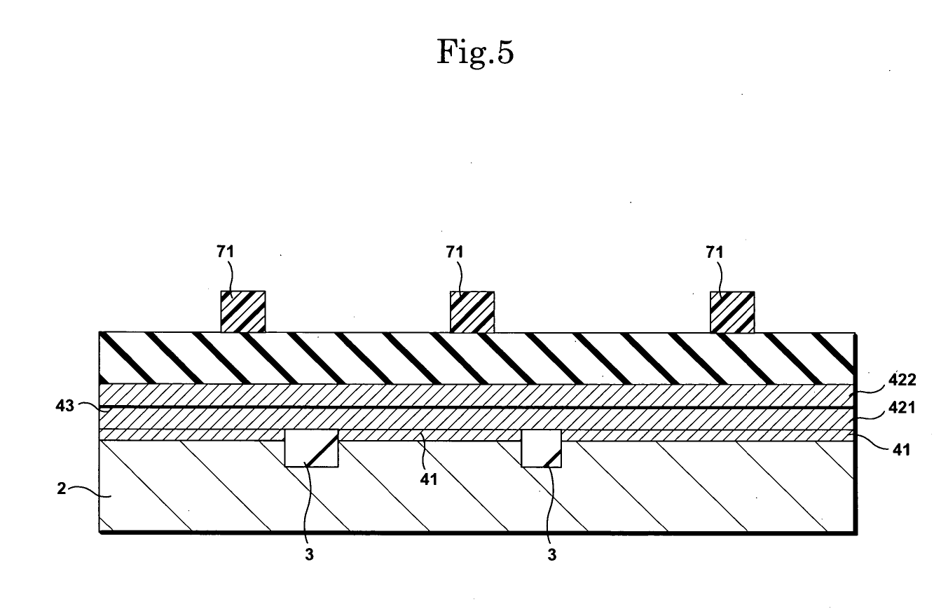

An insulation layer 70 is formed on the entire surface of the second semiconductor 422 (See FIG. 5). This insulation layer 70 forms an opening part in which the second main electrode 44 is laid. It is possible to use a silicon nitride (Si₃N₄) film which is deposited by a plasma CVD method, for example, on the insulation layer 70, and the layer thickness of this insulation layer 70 is, for example, 100 nm. As is shown in FIG. 5, a mask 71 is formed in the formation area of the transistor 4 on the insulation layer 70. This mask 71 is used a mask which patterns the pillar shaped semiconductor layer 42 of the transistor 4 and, for example, is formed by photo lithography technology.

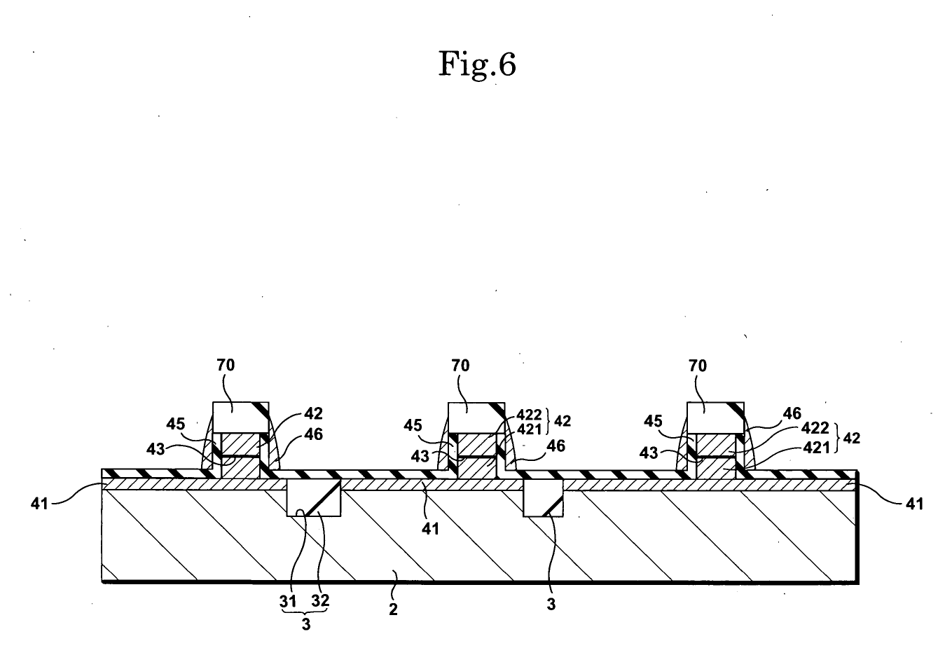

The mask 71 is used as an etching mask and the insulation layer 70 below the mask 71 is patterned (See FIG. 6). At this point, the mask 71 is removed. The insulation layer 70 which has been patterned is used as an etching mask, etching is performed which cuts in order the second semiconductor layer 422, the tunnel insulation layer 43 and the first semiconductor layer 421 and the second semiconductor layer 422, the tunnel insulation layer 43 and the first semiconductor layer 421 form the pillar shaped semiconductor layer 42 which is patterned (See FIG. 6). Anisotropic etching such as RIE is used in this patterning. The insulation layer 70 is used as an oxidation resistant mask, the side area of the pillar shaped semiconductor layer 42 is oxidized and an insulation layer 45 is formed. The insulation layer 45 is a silicon oxide layer which is used as a gate insulation layer in the first embodiment. The layer thickness of this silicon oxide layer is, for example, 2 nm-15 nm. The insulation layer 45 is formed on the side surface of the pillar shaped semiconductor layer 42 and at the same time is also formed on the surface of the first main electrode 41. As is shown in FIG. 6, a control electrode 46 is formed on the side surface of the pillar shaped semiconductor 42 interposed by the insulation layer 45. The control electrode 46 is formed by the following steps. A silicon amorphous layer, for example, is deposited on the entire substrate surface which includes above the insulation layer 45 and above the insulation layer 70. By receding the layer thickness of the silicon amorphous layer by the thickness of the deposited layer, the control electrode 46 is formed on the side wall of the pillar-shaped semiconductor layer 42 and on the surface of insulation layer 45. It is possible to use anisotropic etching such as RIE in the recession of the silicon amorphous layer. The control electrode 46 is formed by self alignment towards the pillar shaped semiconductor layer 42.

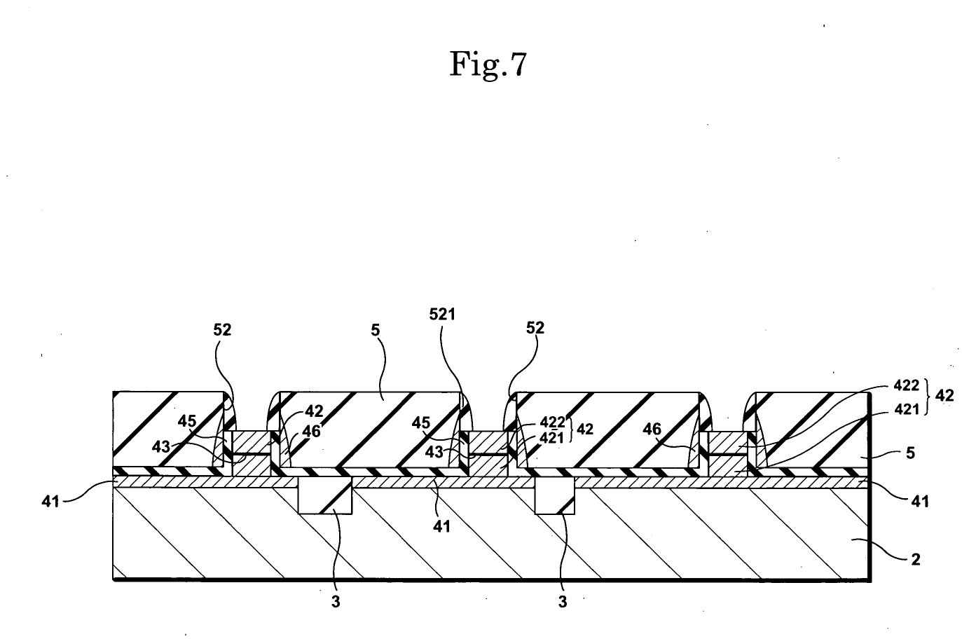

An interlayer insulation layer 5 is formed on the entire surface of the substrate 2 including above the insulation layer 70 (See FIG. 7). In order to completely lay the insulation layer 70, for example, the interlayer insulation layer 5 is formed (at a thickness) more than a layer thickness which corresponds to a dimension from the main surface of the substrate 2 as far as the upper surface of the insulation layer 70. A BPSG (Boron Phosphorous Silicon Glass) layer, for example, is used in the interlayer insulation layer 5. Following depositing, the BPSG layer is planarized by, for example, CMP (chemical mechanical polishing) until the surface of the insulation layer 70 is exposed.

The interlayer insulation layer 5 is used as an etching mask and the insulation layer 70 above the pillar shaped semiconductor layer 42, which is formed first, is removed (See FIG. 7). By removing this insulation layer 70, an opening 52 (a through hole) is formed on the pillar shaped semiconductor layer 42 in the interlayer insulation layer 5. As is shown in FIG. 7, a spacer 521 is formed on the inner wall of the opening 52. The spacer 521 is formed by the following steps. A silicon nitride layer, for example, is deposited using a plasma CVD method on the entire surface above the interlayer insulation layer 5 which includes, for example, above the inner wall and above the bottom surface of the opening 52. It is possible to form the spacer 521 by removing the silicon nitride layer by an amount which corresponds to this deposited layer thickness using anisotropic etching such as RIE. At this moment, the spacer 521 is formed with the aim of preventing an electrical short circuit between the control electrode 46 and the second main electrode 44. Subsequently, when the height from the main surface of the substrate 2 of the control electrode 46 is lower than the height of the insulation layer 45, in other words, if the control electrode 46 is a category of the insulation layer 45, because there is no longer an electrical short circuit between the control electrode 46 and the second main electrode 44 there is not always a need for the spacer 521.

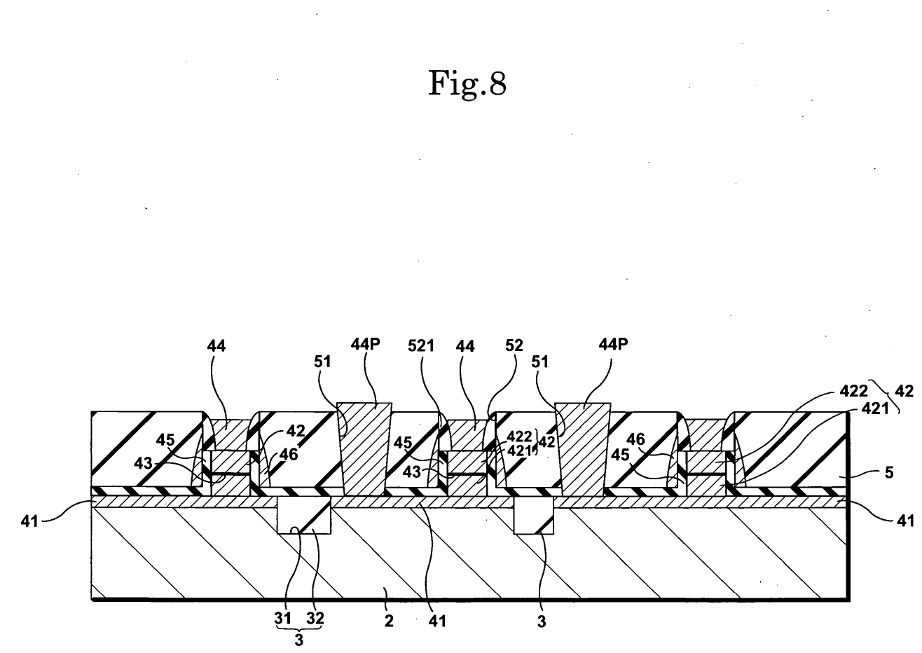

The second main electrode 44 is laid within the opening 52 formed in the interlayer insulation layer 5 interposed by the spacer 521 (See FIG. 8). The second main electrode 44 is formed by the following steps. A silicon amorphous layer, for example, is deposited interposed by a CVD method on the entire surface above the interlayer insulation layer 5 which includes, for example, above the inner part of the opening 52. Impurities which reduce the resistance value, for example, in the first embodiment, arsenic which is an n type impurity, are introduced to this silicon amorphous layer during depositing or after depositing. The silicon amorphous layer is removed using an anisotropic etching such as RIE by an amount which corresponds to a layer thickness which is deposited and the second main electrode 44 is formed only in within the opening 52. When this second main electrode 44 is formed it is possible to complete the transistor 4 which is arranged which the first main electrode 41, the pillar shaped semiconductor layer 42, the second main electrode 44, the insulation layer 45 and the control electrode 46.

Alternatively, On the other hand, an opening 51 (contact hole) is formed on the interlayer insulation layer 5 above the area where the first main electrode 44 is extended from the area where the pillar shaped semiconductor layer 42 is arranged of the main surface of the substrate 2. Then, a plug wire 44P is laid in this opening 51 (See FIG. 8). As is shown in FIG. 8, a wire 6 is formed above the interlayer insulation layer 5. The wire 6 is arranged above the second main electrode 44 and is electrically connected to the second main electrode 44 and another wire 6 is also arranged above the plug wire 44P and is electrically connected to the plug wire 44P. It is possible to effectively use, for example, a barrier metal layer and a laminated film of an aluminum alloy layer which is laminated above the barrier metal layer in the wire 6. A compound layer which laminates a nitride titanium layer (TiN) to a titanium layer (Ti) is used in the barrier metal layer. It is possible to effectively use an aluminum alloy layer which has been added with at least, for example, either Si or Cu as an additive, in the aluminum alloy layer.

When this series of manufacturing processes are completed, a semiconductor device arranged with the transistor 4 relating to the first embodiment of this invention is completed.

Since the pillar shaped semiconductor layer 42 is arranged with a tunnel insulation layer 43 in the semiconductor device relating to the first embodiment, it is possible to sufficiently secure a main current at the time of an ON operation of the transistor 4 and it is possible to reduce a leak current at the time of a CUT-OFF operation of the transistor 4.

### Second Embodiment

In a second embodiment of this invention, an explanation will be given of an example which applies this invention to a semiconductor device which is arranged with a NOR type flash memory which comprises memory cells using a transistor relating to the previously stated first embodiment. The NOR type flash memory is a non-volatile memory and an electrical block erasure type non-volatile memory.

[NOR Type Flash Memory Circuit Construction]

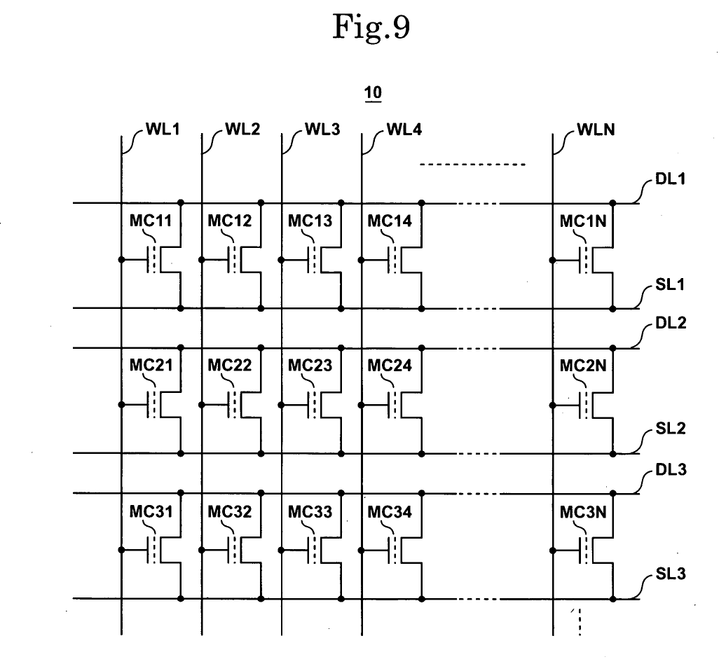

As is shown in FIG. 9, a memory cell array of a NOR type flash memory 10 is arranged with a data line DL1, DL2, DL3, . . . and a source line SL1, SL2, SL3, . . . and a word line WL1, WL2, WL3, . . . . The data line DL in the center of the diagram is extended in a lateral direction and is arranged so that it separates at a fixed pitch in a vertical direction. The source line SL is extended in a horizontal direction parallel with the data line DL and is arranged so that it separates at a fixed pitch in a vertical direction. The data line DL and the source line SL are arranged alternately in series in a vertical direction. The world line WL extends in a vertical direction, in the centre of the diagram, and is arranged so that it separates at a fixed pitch in a lateral direction.

Memory cells MC11-MC1N are arranged between the data line DL and the source line SL from the left side to the right side. A first main electrode (source electrode or a source region) of each of the memory cells MC11-MC1N is electrically connected to the source line SL1, and each second main electrode (drain electrode or a drain region) is electrically connected to the data line DL1. The word line WL1 is electrically connected to the memory cell MC11 and the word line WL2 is electrically connected to the memory cell MC12 and the word line WLN is electrically connected to the memory cell MC1N.

Similarly, between the data line DL2 and the source line SL2 the memory cells MC21-MC2N are arranged in series. The first main electrode of each of the memory cells MC21-MC2N is electrically connected to the source line SL2 and each second main electrode is electrically connected to the data line DL2. The word line WL1 is electrically connected to the memory cell MC21, the word line WL2 is electrically connected to the memory cell MC22 and the world line WLN is electrically connected to the memory cell MC2N. The memory cells MC31-MC3N are arranged in series between the data line DL3 and the source line SL3. The first main electrode of each of the memory cells MC31-MC3N is electrically connected to the source line SL3 and each second main electrode is electrically connected to the data line DL3. The word line WL1 is electrically connected to the memory cell MC31, the word line WL2 is electrically connected to the memory cell MC32 and the word line WLN is electrically connected to the memory cell MC32N. While a detailed cross sectional construction will be explained later, the memory cell MC of the first embodiment is comprises of an n channel type IGFET which has a charge accumulating region.

[NOR Type Flash Memory Circuit Operation]

Data Program Operation

The data program operation to the memory cell of the NOR type flash memory is as follows. This example explains the selection of a memory cell MC 11 and a data program operation to this memory cell MC11. Firstly, 0 V is applied to all the source lines SL1, SL2, . . . and the memory cell MC11 which becomes the object of the data program is connected to a selection data line DL1 which is applied with a positive high voltage HV, and connected to a selection word line WL1 which is applied with a positive high voltage HV and a channel formation region (a pillar shaped semiconductor layer 42 in the second embodiment) is set at 0 V. Based on the conditions of this data program, the electrons which are injected from the channel formation region (pillar shaped semiconductor layer) to the charge accumulating region and which become data are trapped in the memory cell MC11. The electrons flow through the tunnel insulation layer (gate insulation layer) interposed by a tunnel current and are trapped. By injecting electrons into the charge accumulating region the threshold voltage becomes higher in the selected memory cell MC11. In other words, data is programmed to the memory cell MC11.

Data Erasure Operation

The data erasure operation in the memory cell MC of the NOR type flash memory 10 is as follows. All of the source lines SL1, SL2, . . . are applied with a positive high voltage HV, all of the data lines DL1, DL2, . . . are kept in a floating (open) state, all the word lines WL1, WL2, . . . are applied with 0 V or a negative high voltage HV and the channel formation region is set at 0 V. Based on the conditions of this data erasure, electrons are extracted from the charge accumulating region to the channel formation region interposed by the FN phenomenon (Fowler-Nordheim tunneling), which is produced near the first main electrode (source electrode or source region) of the channel formation region and the threshold voltage of the memory cell, MC becomes lower. In other words, the erasure operation of the memory cell MC is performed.

Data Read Operation

The data read operation of a memory cell of the NOR type flash memory 10 is as follows. This example explains the selection of a memory cell MC 11 and a read operation of data programmed to this memory cell MC11. All the source lines SL1, SL2, . . . are applied with 0 V, the selected data line DL1 which is connected to the selected memory cell MC11 is set with a positive low voltage LV, the selected word line WL1 is set with a read voltage RV (low Vₜₕ<RV<high Vₜₕ) and the channel formation region is set at 0 V. Based on the conditions of this data read, a selected memory cell MC detects an ON operation or an OFF operation. For example, the selected word line WL1 is applied with a read voltage RV, and when the threshold voltage Vₜₕ is high the memory cell MC11 is in an OFF operation. The selected word line WL1 is applied with a read voltage RV, and when the threshold voltage Vₜₕ is low the memory cell MC11 is in an ON operation. Depending on whether a current flows through a memory cell MC between a data line DL1 and a source line SL1, it is possible to recognize the threshold voltage Vₜₕ of the memory cell MC11 and it is possible to read the data programmed to the memory cell MC11.

[Construction of a Nor Type Flash Memory]

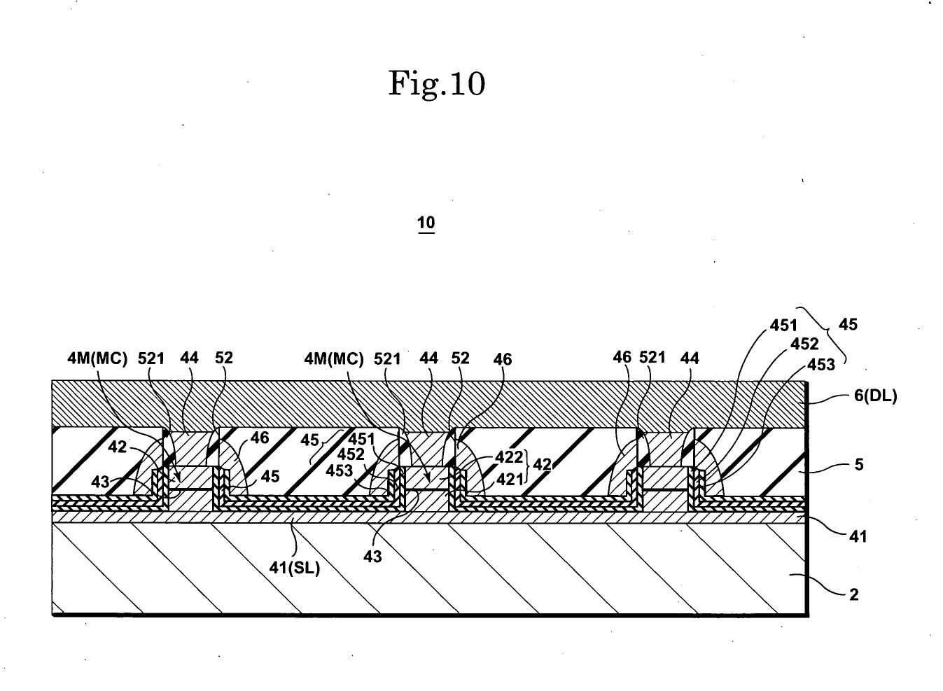

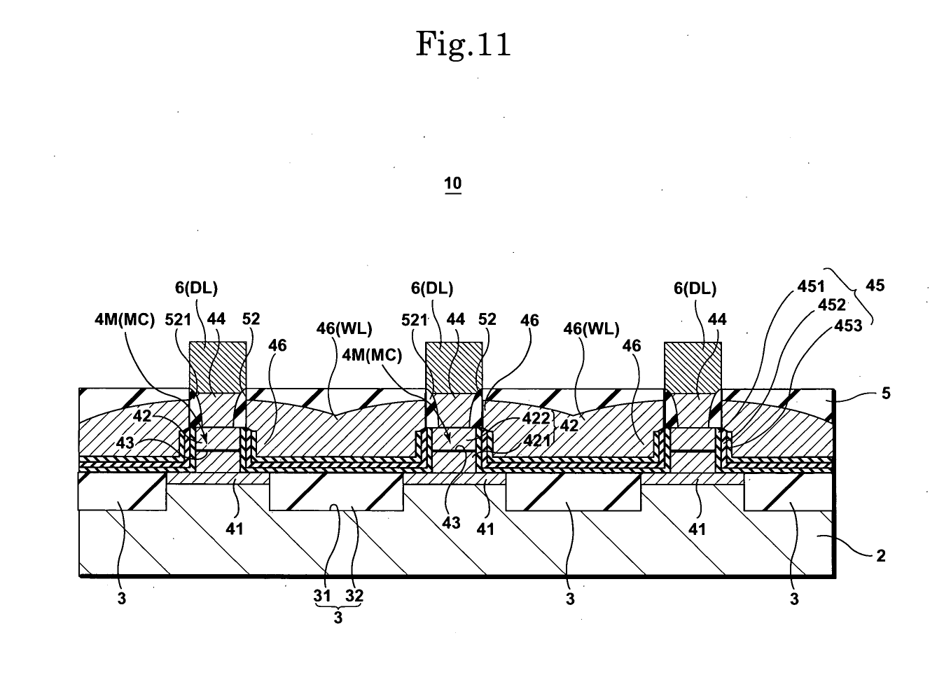

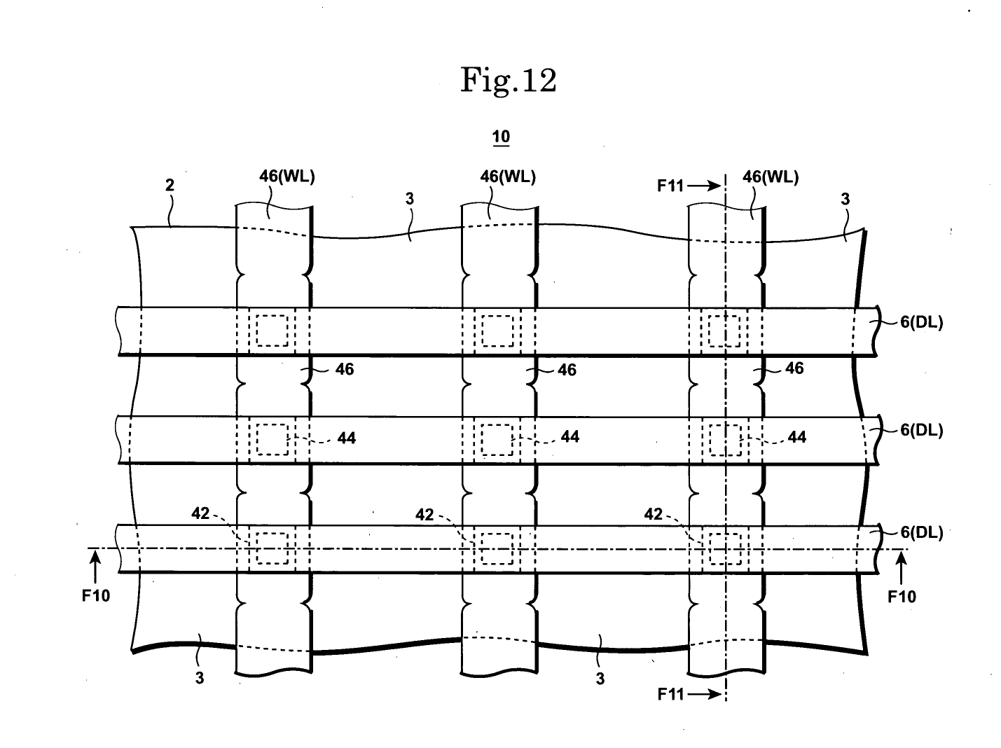

A NOR type flash memory 10 relating to the second embodiment of this invention is comprised of a substrate 2 on a main body as shown in FIG. 10, FIG. 11 and FIG. 12 the same as in the semiconductor device 1 relating to the previously stated first embodiment. A silicon single crystal substrate, for example, is used in the substrate 2. A memory cell 4M (the memory cell shown in FIG. 9) is mounted in the area which is surrounded by an isolation area 3 on the main surface (here an isolation formation surface) of this substrate 2. The memory cell 4M has a vertical type construction the same as the transistor 4 in the first embodiment and is an n channel conductive type IGFET which has a charge accumulating region.

The isolation area 3 is constructed in an STI construction. That is, the isolation area 3, the same as the isolation area 3 relating to the first embodiment, is arranged with a trench 31 which is formed in a depth direction from the main surface of the substrate 2 and an insulation body 31 which is laid within this trench 31. Furthermore, the isolation area 3 can be comprised by a field oxide layer which is formed by selectively oxidizing the main surface of the substrate 2.

The memory cell 4M is arranged with a first main electrode 41 which is formed on the main surface of the substrate 2, a pillar shaped semiconductor layer 42 which is formed on the first main electrode and has a poly crystal, a second main electrode 44 which is formed on the pillar shaped semiconductor layer 42, an insulation layer 45 which is formed on the side surface of the pillar shaped semiconductor layer 42 and has a charge accumulating region (corresponding to symbol 452), a control electrode 46 which is formed interposed by the insulation layer 45 on the side surface of the pillar shaped semiconductor layer 42 and a tunnel insulation layer 43 which intersects a main current pathway in the pillar shaped semiconductor layer.

The first main electrode 41 of the memory cell 4M is formed by a semiconductor region which is formed by introducing impurities in a depth direction from the surface of the substrate 2. The first main electrode 41 is used, for example, as a source electrode (or a drain electrode) of the memory cell 4M. The first main electrode 41 relating to the second embodiment is connected (becomes one unit) between the memory cell 4M which adjoins in a direction corresponding to a lateral direction in FIG. 9 and forms a source line SL. The first main electrode 41 is electrically separated by the isolation area 3 within the memory cell 4M which adjoins in a direction which corresponds to a vertical direction in FIG. 9.

The pillar shaped semiconductor layer 42, the same as the pillar shaped semiconductor layer 42 of the transistor 4 relating to the first embodiment, is used as a channel formation region. The pillar shaped semiconductor layer 42 is arranged with the first semiconductor layer 421 which is arranged on the lower side (substrate 2 side) and connected to the first main electrode 41 and the second semiconductor layer 422 which is arranged on the upper side and connected to the second main electrode 44 arranged interposed by the tunnel insulation layer 43 above the first semiconductor layer 421. In other words, the pillar shaped semiconductor 42 is divided into the first semiconductor layer 421 and the second semiconductor layer 422 interposed by the tunnel insulation layer 43. The first semiconductor layer 421 and the second semiconductor layer 422 of this pillar shaped semiconductor layer 42 is in whichever case poly crystal as a final product unrelated to the manufacture process.

Although a detailed cross section construction has been omitted, in the pillar shaped semiconductor 42 in the memory cell 4M shown in FIG. 10 and FIG. 11, the same as the pillar shaped semiconductor 42 shown in the previously stated FIG. 1 relating to the first embodiment, a plurality of grains 4211 and a plurality of grain boundaries 4212 exist in the first semiconductor layer 421. Similarly, a plurality of grains 4221 and a plurality of grain boundaries 4222 exist in the second semiconductor layer 422.

The tunnel insulation layer 43, the same as the tunnel insulation layer 43 relating to the first embodiment, is arranged in the central part of the pillar shaped semiconductor layer 42. The surface layer of the tunnel insulation layer 43 horizontally faces the main surface of the substrate 2. In other words, the layer surface of the tunnel insulation layer 43 is effectively arranged in a lateral direction to the bottom surface or upper surface of the pillar shaped semiconductor layer 42. The tunnel insulation layer 43 is connected from the bottom surface to the upper surface in the pillar shaped semiconductor layer 42, in other words, the seriality of the grains 4212 and the grain boundaries 4222 which connected from the first main electrode 42 to the second main electrode 44 are intersected. In other words, when the operation of the memory cell 4M is OFF, the tunnel insulation layer 43 intersects a leak current which flows through the grain boundaries (4212 and 4222. See FIG. 1) between the first main electrode 41 and the second main electrode 44. Furthermore, when the operation of the memory cell is ON, the tunnel insulation layer allows a main current to flow between the first main electrode 41 and the second main electrode 44 by the tunnel phenomenon.

The tunnel insulation layer 43, the same as the tunnel insulation layer 43 relating to the first embodiment, is constructed from a silicon oxide layer and the layer thickness is set within a range of 0.6 nm to 2.0 nm. The transformation examples such as the number of tunnel insulation layers 43 is the same as the tunnel insulation layer 43 relating to the first embodiment.

The second main electrode 44 is laid interposed by a spacer 521 within the opening 52, which is arranged above the pillar shaped semiconductor layer 42, of the interlayer insulation layer 5 in which the pillar shaped semiconductor layer 42 is laid. The second main electrode 44 is used, for example, as a drain electrode (or a source electrode) of the memory cell 4M. The spacer 521 is arranged in the inner wall of the opening 52 of the interlayer insulation layer 5 and is self aligned with this opening 52 and performs an electrical separation between the second main electrode 44 and the control electrode 46. If the second main electrode 44 and the control electrode 46 are in a state where they are completely electrically insulated then there is not always a need for the spacer 521. The second main electrode 44 is exposed in the area which is surrounded by the bottom surface of the spacer 521 of the opening 52 and makes contact with the upper surface of the pillar shaped semiconductor layer 42 or more precisely, makes contact with and is electrically connected to the upper surface of the second semiconductor layer 422. It is possible to effectively use a single layer of a gate electrode material or a compound layer which includes a gate electrode material in the second main electrode 44, the same as the second main electrode 44 relating to the first embodiment.

The insulation layer 45 is used as at least a gate insulation layer of the memory cell 4M, a tunnel insulation layer or a charge accumulating region. The insulation layer 45 is comprised of a compound layer which includes a first insulation layer 451 which is arranged on the upper surface side of the pillar shaped semiconductor layer 42, a second insulation layer 452 which has a different material to that of the first insulation layer 451 and which is arranged above the first insulation layer 451 and a third insulation layer 453 which is formed by the same material as the first insulation layer 451 and which is arranged above the second insulation layer 452. It is possible to effectively use a silicon oxide layer, for example, which can also be used as a tunnel insulation layer in the first insulation layer 451. The layer thickness of this silicon oxide layer is set, for example, between 2 nm and 5 nm. In the second insulation layer 452, it is possible to effectively use a silicon nitride layer, for example, which has an electron trap level near the surface of the boundary with the first insulation layer 451. This silicon nitride layer is set, for example, between 5 nm and 15 nm. It is possible to effectively use, for example, a silicon oxide layer in the third insulation layer 453. This silicon oxide layer is set, for example, between 5 nm and 20 nm. That is to say, an insulation layer which has an Oxide/Nitride/Oxide (ONO) construction is used in the insulation layer 45 relating to the second embodiment. In other words, the memory cell 4M is comprised of a transistor which has a MONOS (Metal Oxide Nitride Oxide Silicon) construction which has a vertical type construction.

The control electrode 46 is the gate electrode of the memory cell 4M. The control electrode 46 is arranged around the upper side surface of the pillar shaped semiconductor 42 interposed by the insulation layer 45. It is possible to effectively use a single layer of a gate electrode material or a compound layer which has a gate electrode material in the control electrode 46, the same as the control electrode 46 relating to the first embodiment. The control electrode 46 is formed on the side of the pillar shaped semiconductor layer 42 and is self aligned with this pillar shaped semiconductor layer 42. The control electrode 46 relating to the second embodiment is connected (becomes one unit) to the memory cell 4M which is adjacent to the direction which corresponds to a vertical direction in FIG. 9 and constructs a word line WL (See FIG. 11). The control electrode 46 and the memory cell 4M which adjoins the direction which corresponds to a horizontal direction in FIG. 9 are separated and electrically divided (See FIG. 10).

The wire 6 is arranged above the interlayer insulation layer 5. The wire 6 is electrically connected to the second main electrode 44 of the memory cell 4M. The wire 6 is formed by a single layer of a gate electrode material etc or a compound layer which includes a gate electrode material, the same as the wire 6 relating to the first embodiment. The wire 6 relating to the second embodiment is connected (becomes one unit) to the memory cell 4M which is adjacent to the direction which corresponds to a horizontal direction in FIG. 9 and constructs a data line WL. The wire 6 and the memory cell 4M which adjoins the direction which corresponds to a vertical direction in FIG. 9 are separated and electrically divided.

In the NOR type flash memory 10 relating to the second embodiment, a tunnel insulation layer 43 is arranged on the pillar shaped semiconductor 42 of the memory cell 4M. Therefore, when the memory cell 4M is ON, it is possible to sufficiently secure a main current at the time of a data read operation or a data program operation. Furthermore, because it is possible to prevent an increase in a current leak at the time when the memory cell 4M is OFF during a data read operation it is possible to improve a sense margin.

### Third Embodiment

In the third embodiment of this invention, an explanation will be given of an example which applies this invention to a semiconductor device which is arranged with a NAND type flash memory which comprises memory cells using a transistor relating to the previously stated first embodiment. The NAND type flash memory is a non-volatile memory and an electrical block erasure type non-volatile memory.

[NAND Type Flash Memory Circuit Construction]

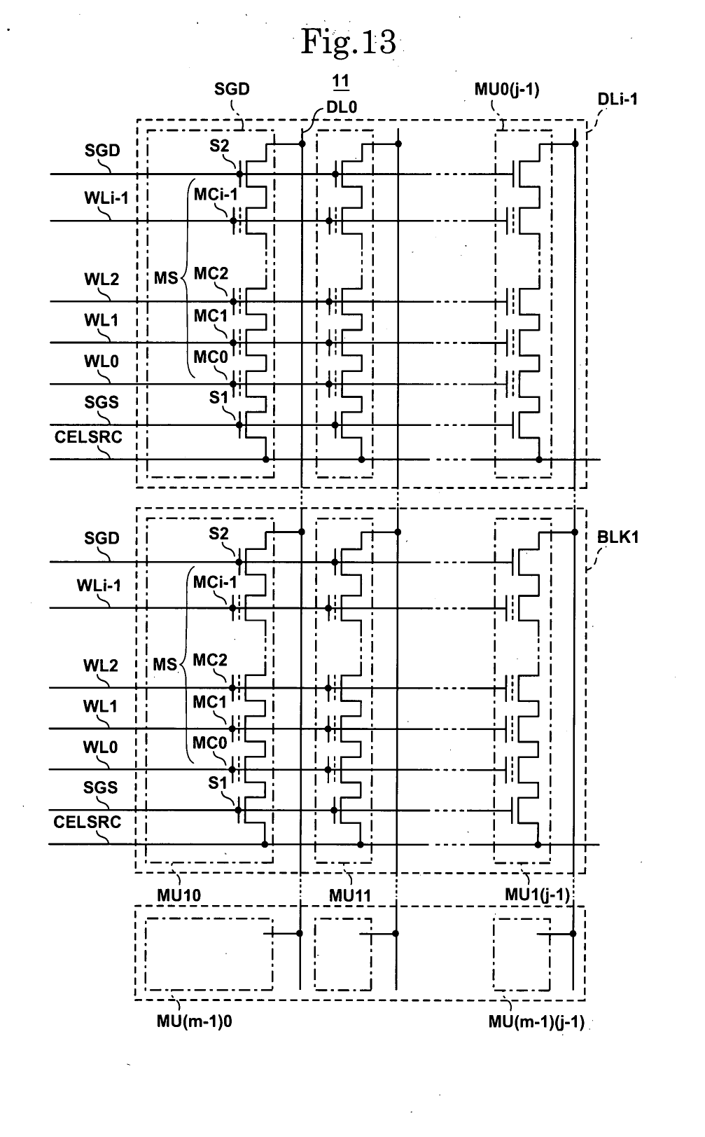

As is shown in FIG. 13, the memory cell array of the NAND type flash memory 10 is comprised of an m number of blocks BLKk (k=0˜m−1) in the third embodiment. Here, “m” is an integer. A plurality of blocks BLKk are arranged on one substrate (on one semiconductor chip. Corresponding to symbol 2 in FIG. 1) and a group of blocks arranged on one substrate is treated as one plane. The block BLKk has a plurality of word lines WLO˜WLi−1 which are extended in a horizontal direction and are arranged in a vertical direction in series at a fixed pitch and a plurality of data lines DL0˜DLj−1 which are extended in a vertical direction and are arranged in a horizontal direction in series at a fixed pitch which intersect these word lines WL0˜WLi−1. Here, “i” and “j are integers. A memory unit MU is arranged where the word lines WLO and the data line DL0 intersect. More specifically, in the block BLKk, a memory unit MU00 is arranged at the part where the data line DL0 and the plurality of word lines WLO˜WLi−1 intersect, a memory unit MU01 is arranged at the part where the data line DL1 and the plurality of word lines WLO˜WLi−1 intersect and a memory unit MU0 (j−1) is arranged at the part where the data line DLj−1 and the plurality of word lines WLO˜WLi−1 intersect. In the block BLK1, a memory unit MU10 is arranged at the part where the data line DL0 and the plurality of word lines WLO˜WLi−1 intersect, a memory unit MU11 is arranged at the part where the data line DL1 and the plurality of word lines WLO˜WLi−1 intersect and a memory unit MU1 (j−1) is arranged at the part where a bit line BLj−1 and the plurality of word lines WLO˜WLi−1 intersect. Below, in the block BLKm−1, a memory unit MU is similarly arranged and a memory unit MU (m−1) (j−1) is arranged in a final line position.

Each memory unit MU of each memory block BLK is arranged with a memory string MS which is electrically connected in series to each of the memory cells MC0˜MCi−1, a first selection transistor S1 which is electrically connected in series to one end of this memory string MS and a second selection transistor S2 which is electrically connected in series to the other end of the memory string MS. The first selection transistor S1 and the second selection transistor S2 are both formed by n channel conductive type IGFET in the third embodiment. A selection signal line SGS is electrically connected to the gate electrode of the first selection transistor S1 and a source line CELSRC is electrically connected to one main electrode area (for example, a source electrode or a source area). A selection signal line SGD is electrically connected to a gate electrode of the second selection transistor S2 and a data line DL is electrically connected to one main electrode area (for example, a drain electrode or a drain area).

Here, as will be stated in the third embodiment, the memory cell MC is formed essentially by the same construction as the memory cell 4M relating to the previously stated second embodiment. In other words, the memory cell MC is formed by an n channel conductive type IGFET which has a charge accumulating region. The memory cell MC which adjoins in a direction (the same direction as the extended direction of the bit line BL) which is electrically connected is series is comprised of one unit which shares one main electrode each other. Here, the number of series of the memory cell MC of the memory string MS in the memory unit MU is not especially limited, however, it is set at multiples of 2. In the NAND flash memory 11 relating to the third embodiment, a group of a plurality of memory cells MC which are connected to one word line WL become a page unit.

[NAND Type Flash Memory Construction]

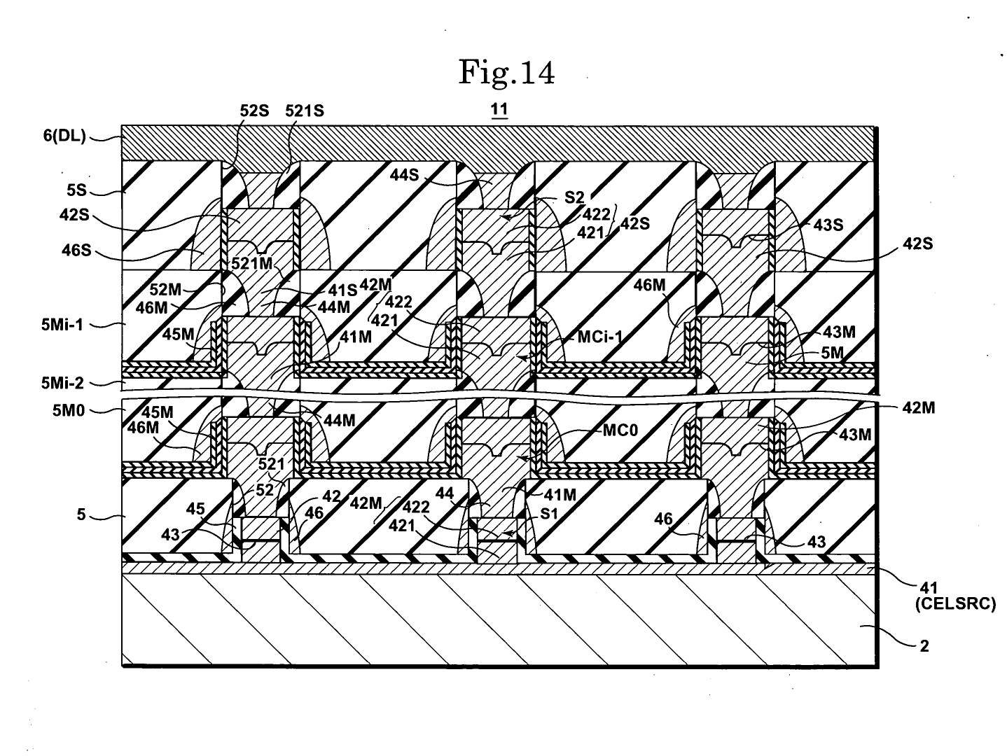

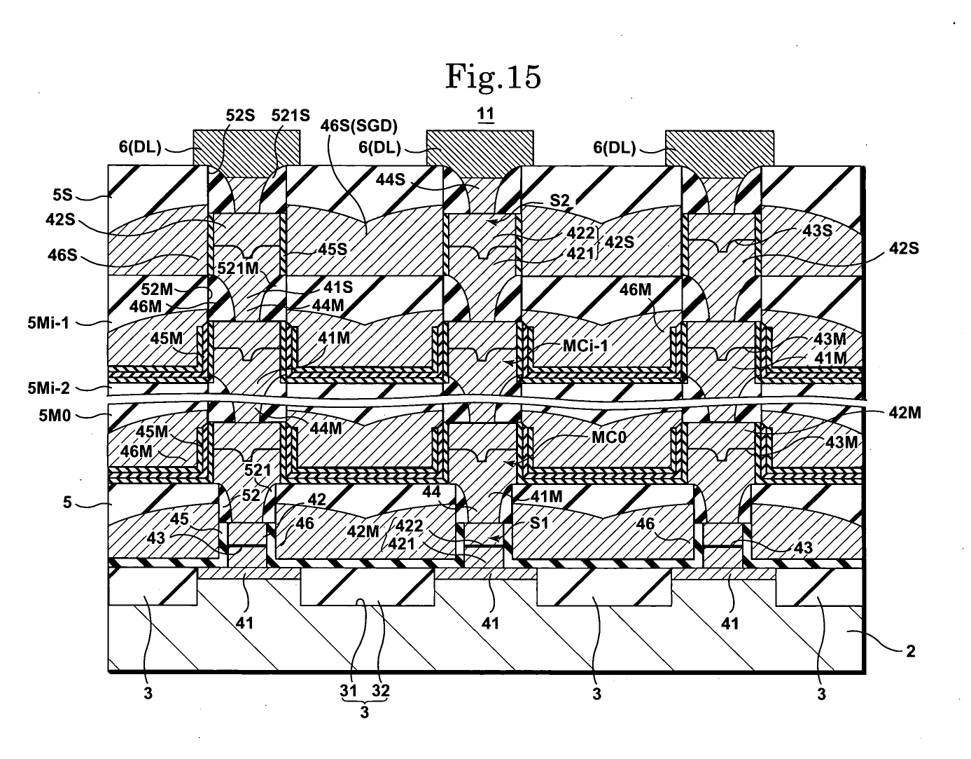

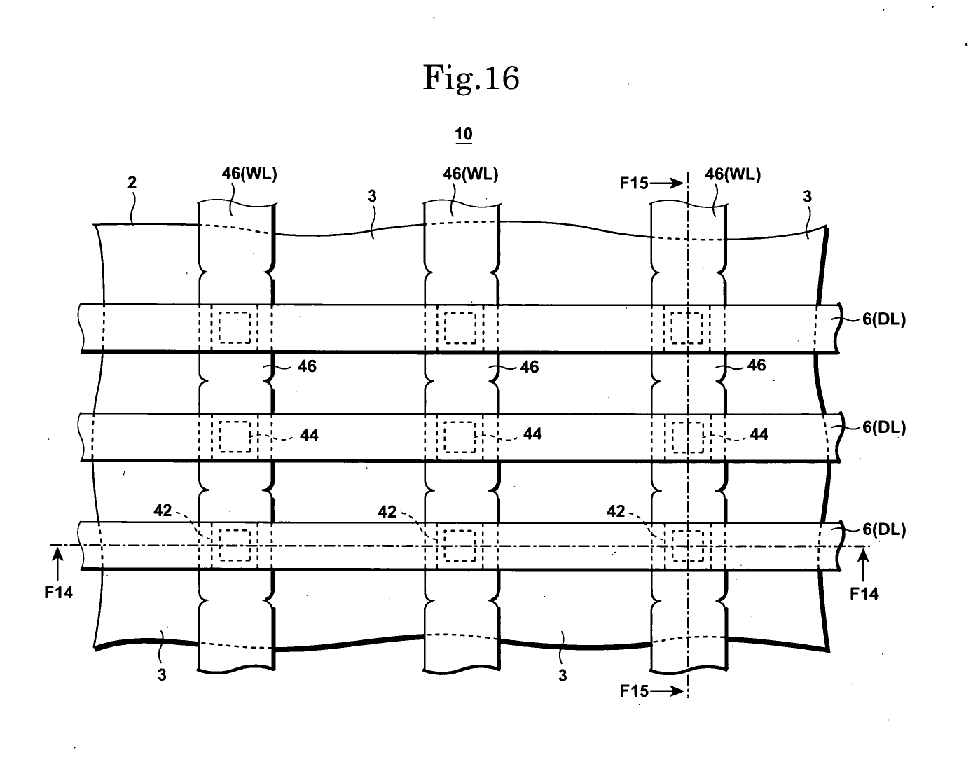

The NAND type flash 11 memory relating to the third embodiment of this invention, the same as the NOR type flash memory 10 relating to the previously stated second embodiment as well as the semiconductor device 1 relating to the previously stated first embodiment, as is shown in FIG. 14, FIG. 15 and FIG. 16, is formed of a substrate 2 on a main body. A silicon single crystal substrate is used, for example, in the substrate 2. A first selection transistor S1 of the memory cell unit MC shown in FIG. 13 is mounted in an area surrounded by an isolation area 3 on the main surface (here, element forming surface) of this substrate 2. Then, the memory cell MC of the memory string MS is built in layers in a perpendicular direction to the main surface of the substrate 2 above the first selection transistor S1 and the second selection transistor S2 is mounted above the memory cell MC (MCi−1) of the highest layer. That is, the NAND flash memory 11 relating to the third embodiment is formed of a three dimensional construction where the first transistor S1, the memory cell MC of the memory string MS and the second selection transistor S2 are each built in order in layers.

The isolation area 3 is formed by an STI (Shallow Trench Isolation) construction. That is, the isolation area 3 is arranged with a trench 31 which is formed in that depth direction from the main face of substrate 2 and an insulator 31 which is deposited within this trench 31. Furthermore, the isolation area 3 can also be constructed by a field oxide film which is formed by selectively oxidizing the main surface of substrate 2.

First Selection Transistor Construction

The first selection transistor S1 of the memory cell unit shown in FIG. 13 is an n channel conductive type IGFET and basically has the same vertical type construction as the transistor 4 relating to the first embodiment stated previously as shown in FIG. 14 and FIG. 15. The first selection transistor S1 is arranged with a first main electrode 41 which is formed on the main surface of the substrate 2 and a pillar shaped semiconductor layer 42 including poly crystal, formed above the first main electrode 41, a second main electrode 44 which is formed above the pillar shaped semiconductor layer 42, an insulation layer 45 which is formed on the side of the pillar shaped semiconductor layer 42, a control electrode 46 which is formed interposed by the insulation layer 45 on the side of the pillar shaped semiconductor layer 42 and a tunnel insulation layer 43 which intersects a main current pathway in the pillar shaped semiconductor layer 42.

The first main electrode 41 of the first selection transistor S1 is formed in detail by the semiconductor region which is formed by introducing impurities in a depth direction from the surface of the substrate 2. The first main electrode 41 is used, for example, as a source electrode (or a drain electrode) of the first selection transistor S1. The first main electrode 41 relating to the third embodiment is connected (becomes one unit) between the first selection transistor S1 which adjoins in a direction corresponding to a lateral direction in FIG. 13 and forms a source line CELSRC. The first selection transistor S1 which adjoins in a direction corresponding to a vertical direction in FIG. 13 and the first main electrode 41 are electrically separated by the isolation area 3.

The pillar shaped semiconductor layer 42, the same as the pillar shaped semiconductor layer 42 of the transistor 4 relating to the first embodiment, is used as a channel formation region. The pillar shaped semiconductor layer 42 is arranged with the first semiconductor layer 421 which is arranged on the lower side (substrate 2 side) and connected to the first main electrode 41 and the second semiconductor layer 422 which is arranged on the upper side and connected to the second main electrode 44 arranged interposed by the tunnel insulation layer 43 above the first semiconductor layer 421. In other words, the pillar shaped semiconductor 42 is divided into the first semiconductor layer 421 and the second semiconductor layer 422 interposed by the tunnel insulation layer 43. The first semiconductor layer 421 and the second semiconductor layer 422 of this pillar shaped semiconductor layer 42 is in whichever case poly crystal as a final product unrelated to the manufacture process.

Although a detailed cross section construction has been omitted, in the pillar shaped semiconductor 42 in the first selection transistor S1 shown in FIG. 14 and FIG. 15, the same as the pillar shaped semiconductor 42 shown in the previously stated FIG. 1 relating to the first embodiment, a plurality of grains 4211 and a plurality of grain boundaries 4212 exist in the first semiconductor layer 421. Similarly, a plurality of grains 4221 and a plurality of grain boundaries 4222 exist in the second semiconductor layer 422.

The tunnel insulation layer 43, the same as the tunnel insulation layer 43 relating to the first embodiment, is arranged in the central part of the pillar shaped semiconductor layer 42. The surface layer of the tunnel insulation layer 43 horizontally faces the main surface of the substrate 2. In other words, the layer surface of the tunnel insulation layer 43 is effectively arranged in a lateral direction to the bottom surface or upper surface of the pillar shaped semiconductor layer 42. The tunnel insulation layer 43 is connected from the bottom surface to the upper surface in the pillar shaped semiconductor layer 42, in other words, the seriality of the grains 4212 and the grain boundaries 4222 which connected from the first main electrode 42 to the second main electrode 44 are intersected. In other words, when the operation of the first selection transistor S1 is OFF, the tunnel insulation layer 43 intersects a leak current which flows through the grain boundaries (4212 and 4222. See FIG. 1) between the first main electrode 41 and the second main electrode 44. Furthermore, when the operation of the first selection transistor S1 is ON, the tunnel insulation layer 43 allows a main current to flow between the first main electrode 41 and the second main electrode 44 by the tunnel phenomenon.

The tunnel insulation layer 43, the same as the tunnel insulation layer 43 relating to the first embodiment, is constructed from a silicon oxide layer and the layer thickness is set within a range of 0.6 nm to 2.0 nm. The transformation examples such as the number of tunnel insulation layers 43 is the same as the tunnel insulation layer 43 relating to the first embodiment.

The second main electrode 44 is laid interposed by a spacer 521 within the opening 52, which is arranged above the pillar shaped semiconductor layer 42, of the interlayer insulation layer 5 in which the pillar shaped semiconductor layer 42 is laid. The second main electrode 44 is used, for example, as a drain electrode (or a source electrode) of the first selection transistor S1. The spacer 521 is arranged in the inner wall of the opening 52 of the interlayer insulation layer 5 and is self aligned with this opening 52 and performs an electrical separation between the second main electrode 44 and the control electrode 46. If the second main electrode 44 and the control electrode 46 are in a state where they are completely electrically insulated then there is not always a need for the spacer 521. The second main electrode 44 is exposed in/to the area which is surrounded by the bottom surface of the spacer 521 of the opening 52 and makes contact with the upper surface of the pillar shaped semiconductor layer 42 or more precisely, makes contact with and is electrically connected to the upper surface of the second semiconductor layer 422. It is possible to effectively use a single layer of a gate electrode material or a compound layer which includes a gate electrode material in the second main electrode 44, the same as the second main electrode 44 relating to the first embodiment.

The insulation layer 45 is the gate insulation layer of the first selection transistor S1. The insulation layer 45 is arranged around the upper side surface of the pillar shaped semiconductor layer 42. It is possible to effectively use a single layer of either a silicon oxide layer, a silicon nitride layer or oxi nitride layer or a compound layer which builds together more than 2 of these varieties.

The control electrode 46 is the gate electrode of the first selection transistor S1. The control electrode 46 is arranged around the upper side surface of the pillar shaped semiconductor 42 interposed by the insulation layer 45. It is possible to effectively use a single layer of a gate electrode material or a compound layer which has a gate electrode material in the control electrode 46, the same as the control electrode 46 relating to the first embodiment. The control electrode 46 is formed on the side of the pillar shaped semiconductor layer 42 and is self aligned with this pillar shaped semiconductor layer 42. The control electrode 46 relating to the third embodiment is connected (becomes one unit) to the first selection transistor S1 which is adjacent to the direction which corresponds to a vertical direction in FIG. 13 and constructs a selection signal line SGS. The control electrode 46 and the first selection transistor S1 which adjoins the direction which corresponds to a horizontal direction in FIG. 13 are separated and electrically divided.

Memory Cell MC0 Construction

The memory cell MC0 of the memory string MS shown in FIG. 14 and FIG. 15 is arranged with a first main electrode 41M which is arranged above the second main electrode 44 of the first selection transistor S1, a pillar shaped semiconductor layer 42M including poly crystal, formed above the first main electrode 41M, a second main electrode 44M which is formed above the pillar shaped semiconductor layer 42M, an insulation layer 45M which is formed on the side of the pillar shaped semiconductor layer 42M and has a charge accumulating region (corresponding to symbol 452), a control electrode 46M which is formed interposed by the insulation layer 45M on the side of the pillar shaped semiconductor layer 42M and a tunnel insulation layer 43M which intersects a main current pathway in the pillar shaped semiconductor layer 42M.

The first main electrode 41M of the memory cell MC0 is electrically connected to the second main electrode 44 of the first selection transistor S1. The first main electrode 41M in the third embodiment is arranged within the opening 52 formed by the interlayer insulation layer 5 and interposed by a the spacer 521 and is formed by becoming one unit with the second main electrode 44 of the first selection transistor S1. Here, one unit means the first main electrode 41M and the second main electrode 44 being formed with the same conductive material formed in the same conductive layer. The first main electrode 41M in the third embodiments formed by one part of the pillar shaped semiconductor 42M, that is, becomes one unit with the first semiconductor layer 421 of the bottom layer side. The first main electrode 41M is formed, for example, by a gate electrode material.

The pillar shaped semiconductor layer 42M, the same as the pillar shaped semiconductor layer 42 of the transistor 4 relating to the first embodiment, is used as a channel formation region of the memory cell MC. The pillar shaped semiconductor layer 42 is arranged with the first semiconductor layer 421 which is arranged on the lower side (first selection transistor side) and connected to the first main electrode 41M and the second semiconductor layer 422 which is arranged on the upper side and connected to the second main electrode 44M arranged interposed by the tunnel insulation layer 43M above the first semiconductor layer 421. In other words, the pillar shaped semiconductor 42M is divided into the first semiconductor layer 421 and the second semiconductor layer 422 interposed by the tunnel insulation layer 43M. The first semiconductor layer 421 and the second semiconductor layer 422 of this pillar shaped semiconductor layer 42M are in whichever case poly crystal as a final product unrelated to the manufacture process.

Although a detailed cross section construction has been omitted, in the pillar shaped semiconductor 42M in the memory cell MC0 shown in FIG. 14 and FIG. 15, the same as the pillar shaped semiconductor 42 shown in the previously stated FIG. 1 relating to the first embodiment, a plurality of grains 4211 and a plurality of grain boundaries 4212 exist in the first semiconductor layer 421. Similarly, a plurality of grains 4221 and a plurality of grain boundaries 4222 exist in the second semiconductor layer 422.

The tunnel insulation layer 43, the same as the tunnel insulation layer 43 relating to the first embodiment as well as the second embodiment, is arranged in the central part of the pillar shaped semiconductor layer 42M. The surface layer of the tunnel insulation layer 43M almost horizontally faces the main surface of the substrate 2. Because the pillar shaped semiconductor layer 42M is formed in the step part of the opening 52 of the base interlayer insulation layer 5, a buckle occurs in line with the step shape particularly on the surface of the first semiconductor layer 421 of the pillar shaped semiconductor layer 42M and a tunnel insulation layer 43M is produced on the surface of the first semiconductor layer 421 where this buckle occurs. Because the tunnel insulation layer 43M can inter buckle sect the seriality of the grain boundaries which are connected from the first main electrode 41M to the second main electrode 44M there is not always a need to form the tunnel insulation layer 43M in a perfect/complete plane. In other words, when the operation of the memory cell MC is OFF, the tunnel insulation layer 43M intersects a leak current which flows through the grain boundaries (4212 and 4222. See FIG. 1) between the first main electrode 41M and the second main electrode 44M. Furthermore, when the operation of the memory cell MC is ON, the tunnel insulation layer 43M allows a main current to flow between the first main electrode 41M and the second main electrode 44M by the tunnel phenomenon.

The tunnel insulation layer 43M, the same as the tunnel insulation layer 43 relating to the first embodiment is constructed from a silicon oxide layer and the layer thickness is set within a range of 0.6 nm to 2.0 nm. The transformation examples such as the number of tunnel insulation layers 43M is the same as the tunnel insulation layer 43 relating to the first embodiment.

The second main electrode 44M is interposed by a spacer 521M and laid in an opening 52M which is arranged on the pillar shaped semiconductor layer 42M of the interlayer insulation layer 5M0 which is formed on the interlayer insulation layer 5 and which is laid in the pillar shaped semiconductor 42M. The second main electrode 44M is, for example, used as a drain electrode (or a source electrode) of the memory cell MC0. The spacer 521M is self aligned with the inner wall of the opening 52 and arranged on the inner wall of the opening 52M of the interlayer insulation layer 5M0 and electrically separates the second main electrode 44M and the control electrode 46M. If the second main electrode 44M and the control electrode 46M are completely and electrically insulated then there is not always a need for the spacer 521. The second main electrode 44M is exposed in the area whose outer side is surrounded by the bottom surface of the spacer 521 of the opening 52M and contacts with and is electrically connected to the upper surface of the pillar shaped semiconductor layer 42M, or more specifically, to the upper surface of the second semiconductor layer 422. It is possible to effectively use a single layer of a gate electrode material or a composite layer which includes a gate electrode material in the second main electrode 44M. Here, the second main electrode 44M is electrically connected to the first main electrode 41M of the memory cell MC1 which builds layers on the upper layer of the memory cell MC0, becomes one unit and serves two purposes. In other words, the second main electrode 44M of the memory cell MC0 is formed by the first main electrode 41M of the memory cell MC1 of the upper layer.

The insulation layer 45M is used as at least a gate insulation layer of the memory cell MC0, a tunnel insulation layer or a charge accumulating region. The same as the insulation layer 45 relating to the second embodiment, the insulation layer 45M is comprised of a compound layer which includes a first insulation layer 451 which is arranged on the upper surface side of the pillar shaped semiconductor layer 42M, a second insulation layer 452 which has a different material to that of the first insulation layer 451 and which is arranged above the first insulation layer 451 and a third insulation layer 453 which is formed by the same material as the first insulation layer 451 and which is arranged above the second insulation layer 452. In other words, the insulation layer 45M is formed, for example, from an insulation layer which has an ONO construction and has a charge accumulating region in the second insulation layer 452.

The control electrode 46M is the gate electrode of the memory cell MC0. The control electrode 46M is arranged around the upper side surface of the pillar shaped semiconductor 42M interposed by the insulation layer 45M. It is possible to effectively use a single layer of a gate electrode material or a compound layer which has a gate electrode material in the control electrode 46M, the same as the control electrode 46 relating to the first embodiment. The control electrode 46M is formed on the side of the pillar shaped semiconductor layer 42M and is self aligned with this pillar shaped semiconductor layer 42M. The control electrode 46M relating to the third embodiment is connected (becomes one unit) to the memory cell MC0 which is adjacent to the direction which corresponds to a horizontal direction in FIG. 13 and constructs a word line WL0 (See FIG. 15). The control electrode 46M and the memory cell MC which adjoins the direction which corresponds to a vertical direction in FIG. 13 are separated and electrically divided (See FIG. 14).

Memory Cell MCi−1 Construction

The memory cell MC1-MCi−1 of the memory string MS is built of layers in order above the memory cell MC0, and is formed by basically the same construction as the memory cell MC0. The memory cell MCi−1 of a final step of the memory string MS, the same as the memory cell MC0, is arranged with a first main electrode 41M arranged above a second main electrode 44M of a memory cell MCi−2 (See the circuit drawing of FIG. 13), a pillar shaped semiconductor layer 42M which is formed above the first main electrode 41M and which has poly crystal, the second main electrode 44M which is formed above the pillar shaped semiconductor layer 42M, an insulation layer 45M which is formed on the side surface of the pillar shaped semiconductor layer 42M and which has a charge accumulating region (corresponding to symbol 452), a control electrode 46M which is formed on the side surface of the pillar shaped semiconductor layer 42M and interposed by the insulation layer 45M and a tunnel insulation layer 43M which intersects a main current pathway in the pillar shaped semiconductor layer 42M.

The first main electrode 41M of the memory cell MCi−1 is electrically connected to the second main electrode 44M of the memory cell MC0. The first main electrode 41M in the third embodiment is arranged within the opening 52M formed in an interlayer insulation layer 5Mi−2 interposed by the spacer 521 and is formed by becoming one unit with the second main electrode 44M of the memory cell MCi−2. The first main electrode 41M, further in the third embodiment, is formed by becoming one unit with one part of the pillar shaped semiconductor layer 42M, in other words, with the first semiconductor 421 of the bottom layer side. The first main electrode 41M is formed, for example, by a gate electrode material.

The pillar shaped semiconductor layer 42M of the memory cell MCi−1, the same as the pillar shaped semiconductor layer 42M of the memory cell MC0, is used as a channel formation region of the memory cell MCi−1. The pillar shaped semiconductor layer 42M is arranged with the first semiconductor layer 421 which is arranged on the lower side (memory cell MCi−2 side) and connected to the first main electrode 41M and the second semiconductor layer 422 which is arranged on the upper side and arranged interposed by the tunnel insulation layer 43M above the first semiconductor layer 421 and is connected to the second main electrode 44M. In other words, the pillar shaped semiconductor 42M is divided into the first semiconductor layer 421 and the second semiconductor layer 422 interposed by the tunnel insulation layer 43M. The first semiconductor layer 421 and the second semiconductor layer 422 of this pillar shaped semiconductor layer 42M, the same as the column shape semiconductor layer 42M of the memory cell MC0, are in whichever case poly crystal as a final product unrelated to the manufacture process.

The tunnel insulation layer 43M, the same as the tunnel insulation layer 43M of the memory cell MC0, is arranged in the central part of the pillar shaped semiconductor layer 42M. The tunnel insulation layer 43M, the same as the tunnel insulation layer 43 of the memory cell MC0 is constructed from a silicon oxide layer and the layer thickness is set within a range of 0.6 nm to 2.0 nm.

The second main electrode 44M is interposed by a spacer 521M and laid in an opening 52M which is arranged above/on the pillar shaped semiconductor layer 42M of the interlayer insulation layer 5Mi−1 which is formed above the interlayer insulation layer 5 and which is laid in the pillar shaped semiconductor 42M. The second main electrode 44M is, for example, used as a drain electrode (or a source electrode) of the memory cell MCi−1. The spacer 521M is self aligned with the opening 52M and arranged on the inner wall of the opening 52M of the interlayer insulation layer 5Mi−1 and electrically separates the second main electrode 44M and the control electrode 46M. If the second main electrode 44M and the control electrode 46M are completely and electrically insulated then there is not always a need for the spacer 521M. The second main electrode 44M is exposed in the area whose outer side is surrounded by the bottom surface of the spacer 521M of the opening 52M and contacts with and is electrically connected to the upper surface of the pillar shaped semiconductor layer 42M, or more specifically, to the upper surface of the second semiconductor layer 422. It is possible to effectively use a single layer of a gate electrode material or a composite layer which includes a gate electrode material in the second main electrode 44M, the same as the second main electrode 44M of the memory cell MC0. Here, the second main electrode 44M in the third embodiment is electrically connected to a first main electrode 41S of a second selection transistor S2 which builds layers on the upper layer of the memory cell MCi−1, becomes one unit and serves two purposes. In other words, the second main electrode 44M of the memory cell MCi−1 is formed by the first main electrode 41S of the second selection transistor S2 of the upper layer.

The insulation layer 45M is used as at least a gate insulation layer of the memory cell MCi−1, a tunnel insulation layer or a charge accumulating region, the same as the insulation layer 45M of the memory cell MC0. The insulation layer 45M is formed, the same as the insulation layer 45M of the memory cell MC0, for example, from an insulation layer which has an ONO construction and has a charge accumulating region in the second insulation layer 452 of the insulation layer 45M.

The control electrode 46M is the gate electrode of the memory cell MCi−1. The control electrode 46M is arranged around the upper side surface of the pillar shaped semiconductor 42M interposed by the insulation layer 45M. It is possible to effectively use a single layer of a gate electrode material or a compound layer which has a gate electrode material in the control electrode 46M, the same as the control electrode 46 of the memory cell MC0. The control electrode 46M is formed on the side of the pillar shaped semiconductor layer 42M and is self aligned with this pillar shaped semiconductor layer 42M. The control electrode 46M relating to the third embodiment is connected (becomes one unit) to the memory cell MCi−1 which is adjacent to the direction which corresponds to a horizontal direction in FIG. 13 and constructs a word line WLi−1 (See FIG. 15). The control electrode 46M and the memory cell MC which adjoins the direction which corresponds to a vertical direction in FIG. 13 are separated and electrically divided (See FIG. 14).

Second Selection Transistor Construction

The second selection transistor S2 of the memory cell unit shown in FIG. 13 is an n channel conductive type IGFET and basically has the same vertical type construction as the first selection transistor S1 stated previously as shown in FIG. 14 and FIG. 15. The second selection transistor S2 is arranged with a first main electrode 41S which is formed above the second main electrode 44M of the memory cell MCi−1, a pillar shaped semiconductor layer 42S including poly crystal, formed above the first main electrode 41S, a second main electrode 44S which is formed above the pillar shaped semiconductor layer 42S, an insulation layer 45S which is formed on the side of the pillar shaped semiconductor layer 42S, a control electrode 46S which is formed interposed by an insulation layer 45S on the side of the pillar shaped semiconductor layer 42S and a tunnel insulation layer 43S which intersects a main current pathway in the pillar shaped semiconductor layer 42S.

The first main electrode 41S of the second selection transistor S2 is electrically connected to the second main electrode 44M of the memory cell MCi−1. The first main electrode 41S in the third embodiment is arranged within the opening 52M formed by the interlayer insulation layer 5Mi−1 and interposed by the spacer 521M and is formed by becoming one unit with the second main electrode 44M of the memory cell MCi−1. Here, the definition of one unit is the same as previously stated. The first main electrode 41S, further in the third embodiment is formed by one part of the pillar shaped semiconductor 42S, that is, becomes one unit with the first semiconductor layer 421 of the bottom layer side. The first main electrode 41S is formed, for example, by a gate electrode material.

The pillar shaped semiconductor layer 42S, the same as the pillar shaped semiconductor layer 42 of the first selection transistor S1, is used as a channel formation region of the second selection transistor S2. The pillar shaped semiconductor layer 42S is arranged with the first semiconductor layer 421 which is arranged on the lower side (first selection transistor S1 side) and connected to and becomes one unit with the first main electrode 41M and the second semiconductor layer 422 which is arranged on the upper side and arranged interposed by the tunnel insulation layer 43S above the first semiconductor layer 421 and is connected to the second main electrode 44S. In other words, the pillar shaped semiconductor 42S is divided into the first semiconductor layer 421 and the second semiconductor layer 422 interposed by the tunnel insulation layer 43S. The first semiconductor layer 421 and the second semiconductor layer 422 of this pillar shaped semiconductor layer 42S are in whichever case poly crystal as a final product unrelated to the manufacture process.

The tunnel insulation layer 43S, the same as the tunnel insulation layer 43 of the first selection transistor S1, is arranged in the central part of the pillar shaped semiconductor layer 42S. The tunnel insulation layer 43S, the same as the tunnel insulation layer 43 is constructed from a silicon oxide layer and the layer thickness is set within a range of 0.6 nm to 2.0 nm.

The second main electrode 44S is interposed by a spacer 521S and laid in an opening 52S which is arranged on the pillar shaped semiconductor layer 42S of the interlayer insulation layer 5S which is formed above the interlayer insulation layer 5Mi−1 and which is laid in the pillar shaped semiconductor 42S. The second main electrode 44S is, for example, used as a drain electrode (or a source electrode) of the second selection transistor S2. The spacer 521S is self aligned with the opening 52S and arranged on the inner wall of the opening 52S of the interlayer insulation layer 5S and electrically separates the second main electrode 44S and the control electrode 46S. If the second main electrode 44S and the control electrode 46S are completely and electrically insulated then there is not always a need for the spacer 521S. The second main electrode 44S is exposed in the area whose outer side is surrounded by the bottom surface of the spacer 521S of the opening 52S and contacts with and is electrically connected to the upper surface of the pillar shaped semiconductor layer 42S, or more specifically, to the upper surface of the second semiconductor layer 422. It is possible to effectively use a single layer of a gate electrode material or a composite layer which includes a gate electrode material in the second main electrode 44S, the same as the second main electrode 44M of the memory cell MC or the second main electrode 44 of the first selection transistor S1.

The insulation layer 45S is used as a gate insulation layer of the second selection transistor S2, the same as the insulation layer 45 of the first selection transistor S1. The insulation layer 45S is formed, for example, from the same material as the insulation layer 45.

The control electrode 46S is the gate electrode of the second selection transistor S2. The control electrode 46S is arranged around the upper side surface of the pillar shaped semiconductor 42S interposed by the insulation layer 45S. It is possible to effectively use a single layer of a gate electrode material or a compound layer which has a gate electrode material in the control electrode 46S, the same as the control electrode 46 of the first selection transistor S1. The control electrode 46S is formed on the side of the pillar shaped semiconductor layer 42S and is self aligned with this pillar shaped semiconductor layer 42S. The control electrode 46S relating to the third embodiment is connected (becomes one unit) to the second selection transistor S2 which is adjacent to the direction which corresponds to a horizontal direction in FIG. 13 and constructs a selection signal line SGD (See FIG. 15). The control electrode 46S and the second selection transistor which adjoins the direction which corresponds to a vertical direction in FIG. 13 are separated and electrically divided (See FIG. 14).

A wire 6 is arranged on the interlayer insulation layer 5S. The wire 6 is electrically connected to the second main electrode 44S of the second selection transistor S2. Although the cross sectional construction is shown simplified, the wire 6 is formed from a barrier metal layer, an aluminum alloy layer above this barrier metal layer and an anti reflection film above this aluminum alloy layer. In the aluminum alloy layer it is possible to effectively use at least an aluminum alloy layer which is at least added in to one additive of either Si or Cu. The wire 6 is connected (becomes one unit) to the second selection transistor which adjoins in a vertical direction in FIG. 13 and forms a data line DL. The wire 6 and the second selection transistor S2 which adjoins the direction which corresponds to a vertical direction in FIG. 13 are separated and electrically divided.

[NAND Type Flash Memory Manufacturing Method]

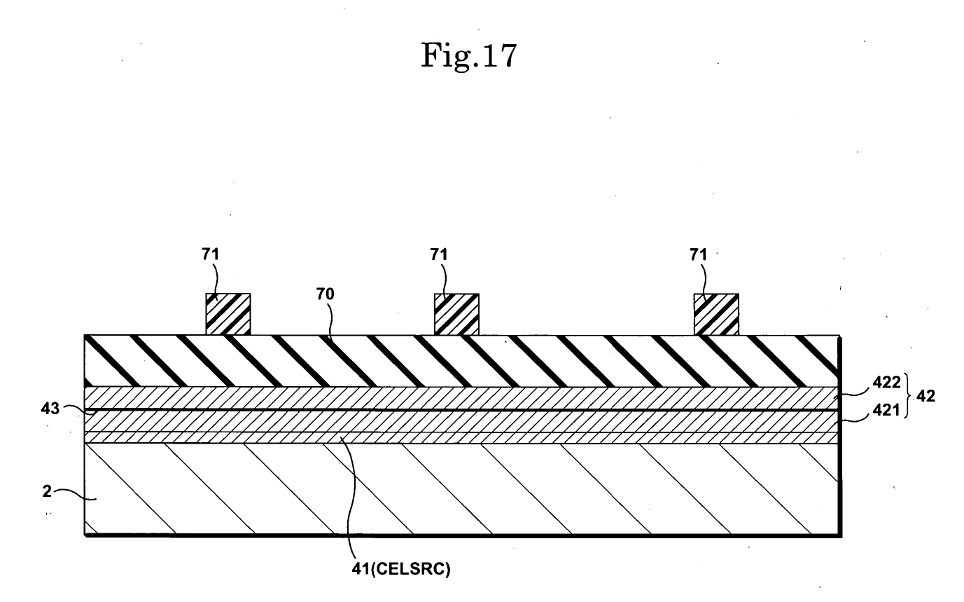

Next, the manufacturing method of the previously stated NAND type flash memory 11 will be explained using FIG. 17 to FIG. 25. Firstly, a substrate 2 is prepared. An isolation area 3 is formed in a non active area on the main surface of this substrate 2 (See FIG. 15). A trench 31 is formed by etching to a depth from the main surface of the substrate 2 using RIE and the isolation area 3 is formed by laying an insulator 32 within this trench 31.

The first main electrode 41 is formed in the active area of the region which is surrounded by the non active area on the main surface of the substrate 2 (FIG. 14, FIG. 15 and FIG. 17). N type impurities are introduced to the main surface part of the substrate 2 using an Ion implantation method and the first main electrode 41 is formed by activating these n type impurities. It is possible to use, for example, at least one of either arsenic (As), or phosphorus (P) in the n type impurities. In addition, it is also possible to use a solid phase diffusion method in the introduction of the n type impurities. The first main electrode 41 forms a source line (CELSRC).

The first semiconductor 421, the tunnel insulation layer 43 and the second semiconductor layer 422 are respectively built in layers in order on the first main electrode 41 and on the entire surface on the main surface of the substrate 2 which includes the isolation area 3 (See FIG. 17). This first semiconductor layer 421, the tunnel insulation layer 43 and the second semiconductor layer 422 form the pillar shaped semiconductor layer 42. The first semiconductor layer 421 is formed by a silicon amorphous layer which has been formed by a CVD method and the layer thickness of the first semiconductor layer 421 is set at 75 nm for example. The tunnel insulation layer 43 is formed by a silicon oxide layer which is formed by oxidizing the surface of the first semiconductor layer 421 at a low temperature. The tunnel insulation layer 43 is formed at low temperature of around 450 degrees Celsius, for example, and the layer thickness of the tunnel insulation layer 43 is between 0.6 nm and 2.0 nm and in the first embodiment is set between 0.8 nm and 1.0 nm. The silicon oxide layer formed by oxidization can obtain a fine layer material. Furthermore, it is possible to form the tunnel insulation layer 43 by the silicon oxide layer or silicon nitride layer deposited in layers by a CVD method or a spattering method. The second semiconductor layer 422 is formed in the same way as the first semiconductor layer 421 by a silicon amorphous layer which is formed by a CVD method and the layer thickness of the second semiconductor layer 422 is set, for example, at 75 nm. In the first embodiment, the first semiconductor layer 421 and the second semiconductor layer 422 are both formed by a silicon amorphous layer and it is possible to improve the diffusion control regulation of the impurities which control a resistance value.

An insulation layer 70 is formed on the entire surface of the second semiconductor 422 (See FIG. 17). This insulation layer 70 forms an opening part in which the second main electrode 44 is laid. It is possible to use a silicon nitride (Si₃N₄) layer which is deposited by a plasma CVD method, for example, on the insulation layer 70, and the layer thickness of this insulation layer 70 is, for example, 100 nm. As is shown in FIG. 17, a mask 71 is formed in the formation area of the first selection transistor S1 on the insulation layer 70. This mask 71 is used as a mask which patterns the pillar shaped semiconductor layer 42 of the first selection transistor S1 and, for example, is formed by photo lithography technology.

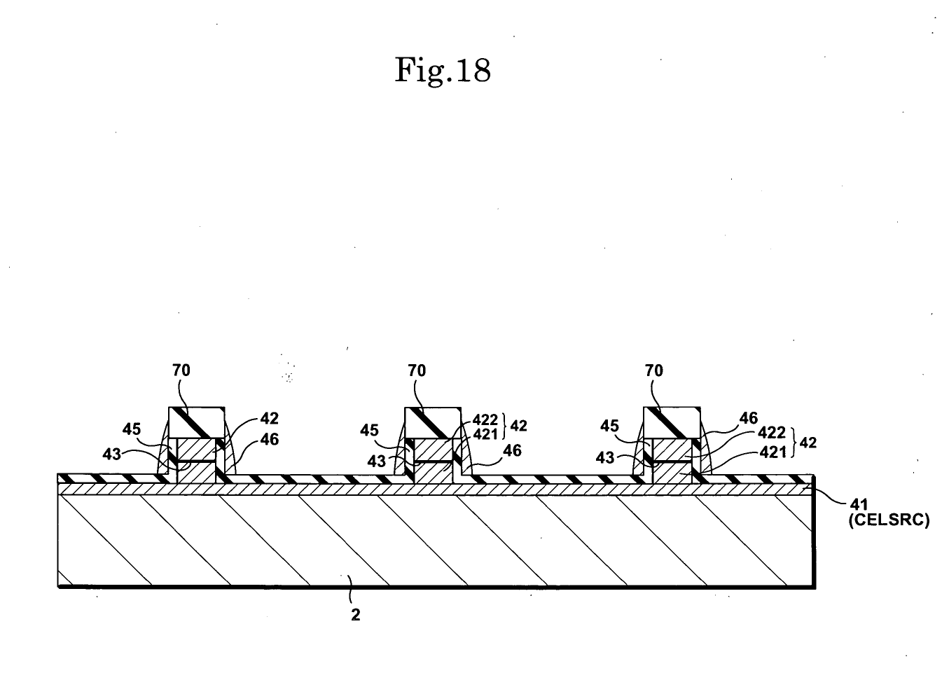

The mask 71 is used as an etching mask and the insulation layer 70 below the mask 71 is patterned (See FIG. 18). At this point, the mask 71 is removed. The insulation layer 70 which has been patterned is used as an etching mask, etching is performed which cuts in order the second semiconductor layer 422, the tunnel insulation layer 43 and the first semiconductor layer 421 and the second semiconductor layer 422, the tunnel insulation layer 43 and the first semiconductor layer 421 form the pillar shaped semiconductor layer 42 which is patterned (See FIG. 18). Anisotropic etching such as RIE is used in this patterning. The insulation layer 70 is used as an oxidation resistant mask, the side area of the pillar shaped semiconductor layer 42 is oxidized and an insulation layer 45 is formed. The insulation layer 45 is a silicon oxide layer which is used as a gate insulation layer in the third embodiment. The insulation layer 45 is formed on the side surface of the pillar shaped semiconductor layer 42 and at the same time is also formed on the surface of the first main electrode 41. As is shown in FIG. 18, a control electrode 46 is formed on the side surface of the pillar shaped semiconductor 42 interposed by the insulation layer 45. The control electrode 46 is formed by the following steps. A silicon amorphous layer, for example, is deposited on the entire substrate surface which includes above the insulation layer 45 and above the insulation layer 70. By receding the layer thickness of the silicon amorphous layer by the thickness of the deposited layer, the control electrode 46 is formed on the side wall of the pillar shaped semiconductor layer 42 and on the surface of insulation layer 45. It is possible to use anisotropic etching such as RIE in the recession of the silicon amorphous layer. The control electrode 46 is formed by self alignment towards the pillar shaped semiconductor layer 42.

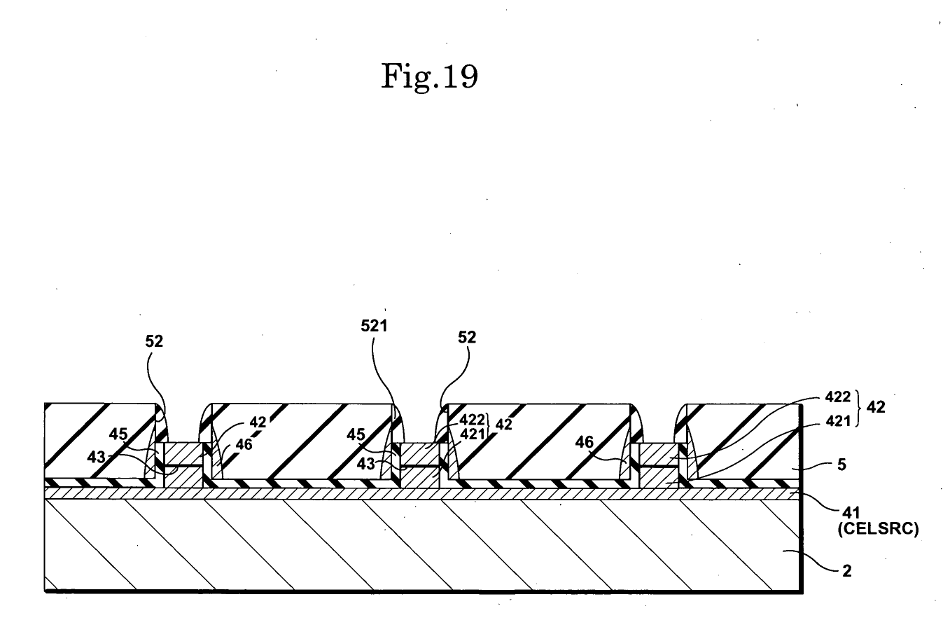

An interlayer insulation layer 5 is formed on the entire surface of the substrate 2 including above the insulation layer 70 (See FIG. 19). In order to completely lay the insulation layer 70, for example, the interlayer insulation layer 5 is formed (at a thickness) more than a layer thickness which corresponds to a size from the main surface of the substrate 2 as far as the upper surface of the insulation layer 70. A BPSG layer, for example, is used in the interlayer insulation layer 5. Following depositing, the BPSG layer is planarized by, for example, CMP until the surface of the insulation layer 70 is exposed.

The interlayer insulation layer 5 is used as an etching mask and the insulation layer 70 above the pillar shaped semiconductor layer 42, which is formed first, is removed (See FIG. 19). By removing this insulation layer 70, an opening 52 (a through hole) is formed on the pillar shaped semiconductor layer 42 in the interlayer insulation layer 5. As is shown in FIG. 19, a spacer 521 is formed on the inner wall of the opening 52. The spacer 521 is formed by the following steps. A silicon nitride layer, for example, is deposited interposed by a plasma CVD method on the entire surface above the interlayer insulation layer 5 which includes, for example, above the inner wall and above the bottom surface of the opening 52. It is possible to form the spacer 521 by removing the silicon nitride layer by an amount which corresponds to this deposited layer thickness interposed by anisotropic etching such as RIE. At this moment, the spacer 521 is formed with the aim of preventing an electrical short circuit between the control electrode 46 and the second main electrode 44. Subsequently, when the height from the main surface of the substrate 2 of the control electrode 46 is lower than the height of the insulation layer 45, in other words, if the control electrode 46 is a category of the insulation layer 45, because there is no longer an electrical short circuit between the control electrode 46 and the second main electrode 44 there is not always a need for the spacer 521.

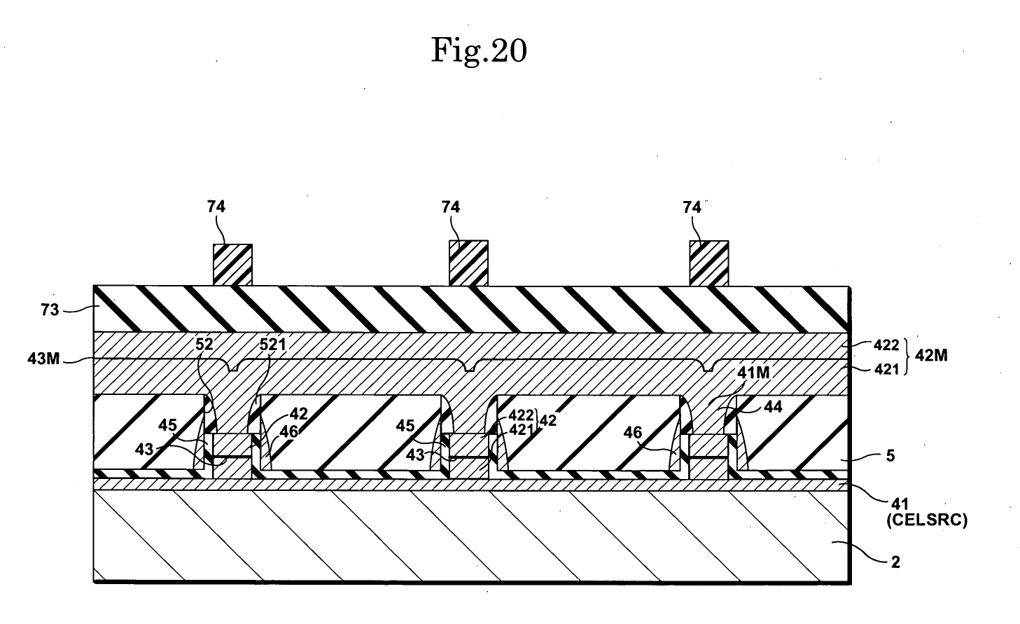

While the second main electrode 44 is laid In the opening 52 which is formed in the interlayer insulation layer 5 interposed by the spacer 521 the first semiconductor layer 421 of the first main electrode 41M or the pillar shaped semiconductor layer 42M is formed (See FIG. 20). By forming the second main electrode 2, the first selection transistor S1 is completed in the memory unit MU of the NAND type flash memory 11. The first semiconductor layer 421 of the first main electrode 41M or the pillar shaped semiconductor layer 42M forms the memory cell MC0 which is built in layers above the first selection transistor S1. A silicon amorphous layer which has been deposited by a CVD method on the entire surface if the interlayer insulation layer 5 for example, is used in the second main electrode 44, the first main electrode 41M and the first semiconductor layer 421. Impurities which reduce the resistance value, for example, in the first embodiment, arsenic which is an n type impurity, are introduced to this silicon amorphous layer during depositing or after depositing.

The tunnel insulation layer 43M, and the second semiconductor layer 422 are respectively accumulated/built in layers in order on the first semiconductor layer 421 which is formed on the entire surface on the main surface of the substrate 2 (See FIG. 20). The previously first semiconductor layer 421, the tunnel insulation layer 43M and the second semiconductor layer 422 form the pillar shaped semiconductor layer 42M. The first semiconductor layer 421 is formed by a silicon amorphous layer which has been formed by a CVD method and the layer thickness of the first semiconductor layer 421 is set at 75 nm for example. The tunnel insulation layer 43M is formed by a silicon oxide layer which is formed by oxidizing the surface of the first semiconductor layer 421 at a low temperature. The tunnel insulation layer 43 is formed at low temperature of around 450 degrees Celsius, for example, and the layer thickness of the tunnel insulation layer 43 is between 0.6 nm and 2.0 nm and in the third embodiment is set between 0.8 nm and 1.0 nm. The silicon oxide layer formed by oxidization can obtain a fine layer material. The second semiconductor layer 422 is formed in the same way as the first semiconductor layer 421 by a silicon amorphous layer which is formed by a CVD method and the layer thickness of the second semiconductor layer 422 is set, for example, at 75 nm. In the third embodiment, the first semiconductor layer 421 and the second semiconductor layer 422 are both formed by a silicon amorphous layer and it is possible to improve the diffusion control regulation of the impurities which control a resistance value.

An insulation layer 73 is formed on the entire surface of the second semiconductor layer 422 (See FIG. 20). This insulation layer 73 forms an opening part in which the second main electrode 44 of the memory cell MC0 is laid. It is possible to use a silicon nitride layer which is deposited by a plasma CVD method, for example, on the insulation layer 73, and the layer thickness of this insulation layer 73 is, for example, 100 nm. As is shown in FIG. 20, a mask 74 is formed in the formation area of the memory cell MC0 on the insulation layer 73. This mask 74 is used as a mask which patterns the pillar shaped semiconductor layer 42M of the memory cell MC0 and, for example, is formed by photo lithography technology.

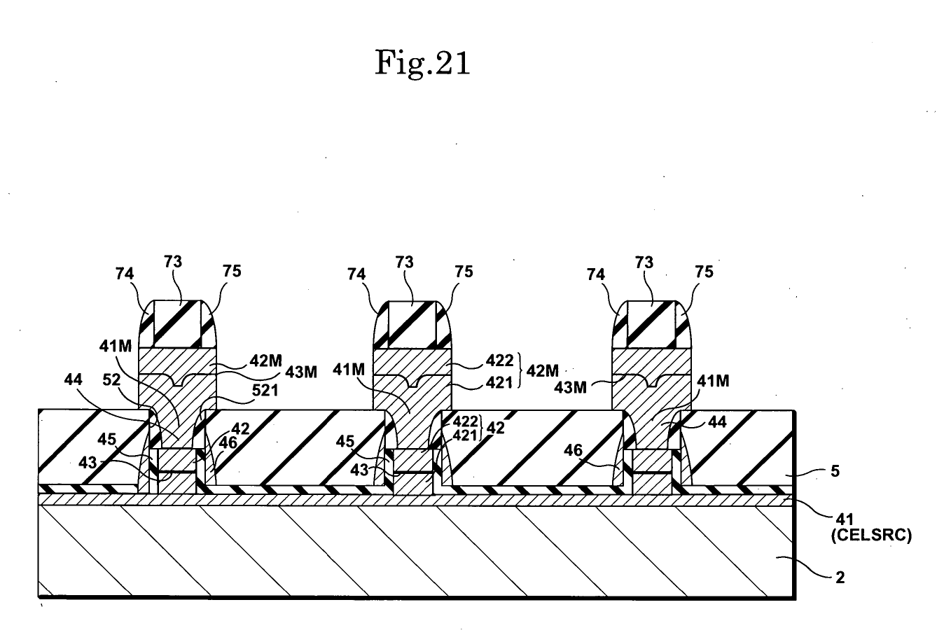

The mask 74 is used as an etching mask and the insulation layer 73 below the mask 74 is patterned (See FIG. 21). Here, the mask 74 is removed. A spacer 75 is formed on the inner wall of the insulation layer 73 (See FIG. 21). It is possible to form the spacer 75, for example, by depositing a silicon nitride layer, for example, interposed by a plasma CVD method, and by etching the entire surface by anisotropic etching such as RIE by an amount which corresponds to the layer thickness of the deposited silicon nitride layer. Also, even in the case where the first main electrode 41M and the pillar shaped semiconductor layer 42M are unaligned with the opening 52 which is formed in the interlayer insulation layer 5, the spacer 75 is formed so that a gap does not occur. The insulation layer 43M and 75 which have been patterned are used as an etching mask and the second semiconductor layer 422, the tunnel insulation 43M and the first semiconductor 421 are removed in order and the second semiconductor 422, the tunnel insulation layer 43M and the first semiconductor layer 421 are formed by the pillar shaped semiconductor layer 42M which has been patterned (See FIG. 21). Anisotropic etching such as RIE is used in this patterning.

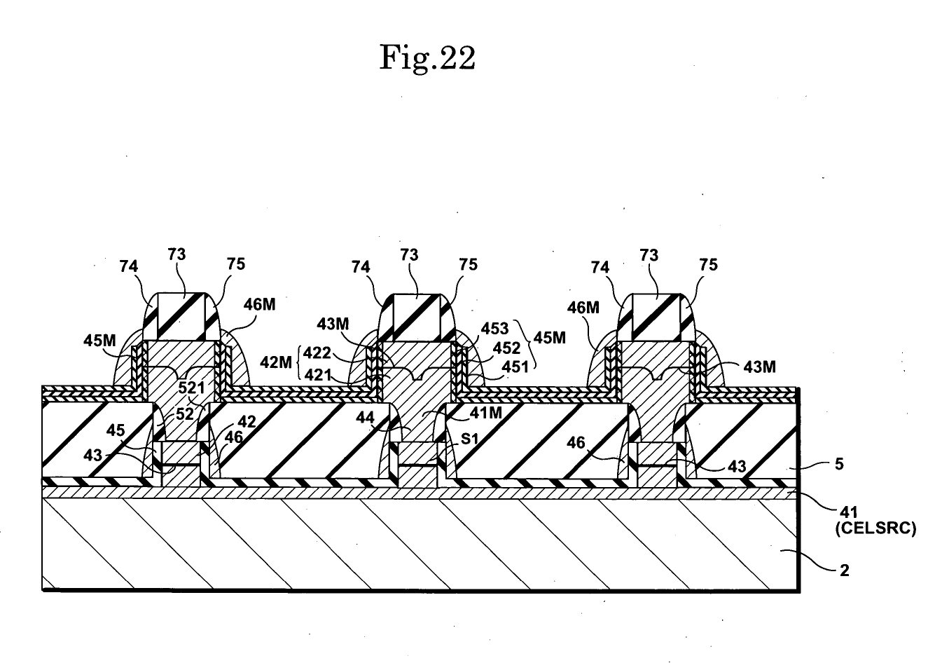

The insulation layer 73 and 75 are used as an oxide resistant mask and the insulation layer 45M is formed around at least the side of the pillar shaped semiconductor layer 42 (See FIG. 22). The insulation layer 45M, the same as the insulation layer 45 of the memory cell 4M relating to the previously stated second embodiment, is formed from an insulation layer of an ONO construction. The insulation layer 45M in the third embodiment is formed on the side surface of the pillar shaped semiconductor layer 42M and at the same time is formed on the surface of the interlayer insulation layer 5. As is shown in FIG. 22, a control electrode 46M is formed on the side surface of the pillar shaped semiconductor 42M interposed by the insulation layer 45M. The control electrode 46M is formed by the following steps. A silicon amorphous layer, for example, is deposited by a CVD method on the entire substrate surface which includes above the insulation layer 45M and above the insulation layer 73 and 75. By receding the layer thickness of the silicon amorphous layer by the thickness of the deposited layer, the control electrode 46M is formed on the side wall of the pillar shaped semiconductor layer 42M and on the surface of insulation layer 45M. It is possible to use anisotropic etching such as RIE in the recession of the silicon amorphous layer. The control electrode 46M is formed by self alignment towards the pillar shaped semiconductor layer 42M.

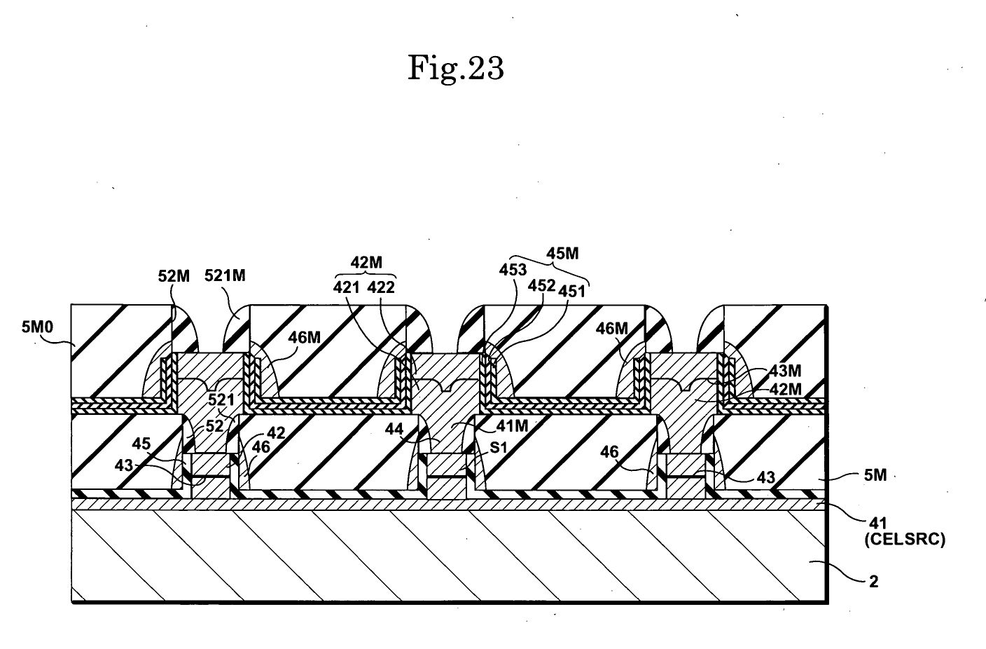

An interlayer insulation layer 5M0 is formed on the entire surface of the substrate 2 including above the insulation layer 73 and 75 (See FIG. 23). In order to completely lay the insulation layer 73 and 75, for example, the interlayer insulation layer 5M0 is formed (at a thickness) more than a layer thickness which corresponds to a size from the main surface of the interlayer insulation layer 5 up to the upper surface of the insulation layer 73. A BPSG layer, for example, is used in the interlayer insulation layer 5M0. Following depositing, the BPSG layer is planarized by, for example, CMP until the surface of the insulation layer 73 is exposed.

The interlayer insulation layer 5M0 is used as an etching mask and the insulation layer 73 and 75 above the pillar shaped semiconductor layer 42M, which is formed first, is removed (See FIG. 23). By removing these insulation layers 73 and 75, an opening 52M (a through hole) is formed on the pillar shaped semiconductor layer 42M in the interlayer insulation layer 5M0. As is shown in FIG. 23, a spacer 521M is formed on the inner wall of the opening 52M. The spacer 521M is formed by the following steps. A silicon nitride layer, for example, is deposited interposed by a plasma CVD method on the entire surface above the interlayer insulation layer 5M0 which includes, for example, above the inner wall and above the bottom surface of the opening 52M. It is possible to form the spacer 521M by removing the silicon nitride layer by an amount which corresponds to this deposited layer thickness interposed by anisotropic etching such as RIE. The spacer 521M is formed on the inner wall of the opening 52M and is self aligned with this opening 52M.

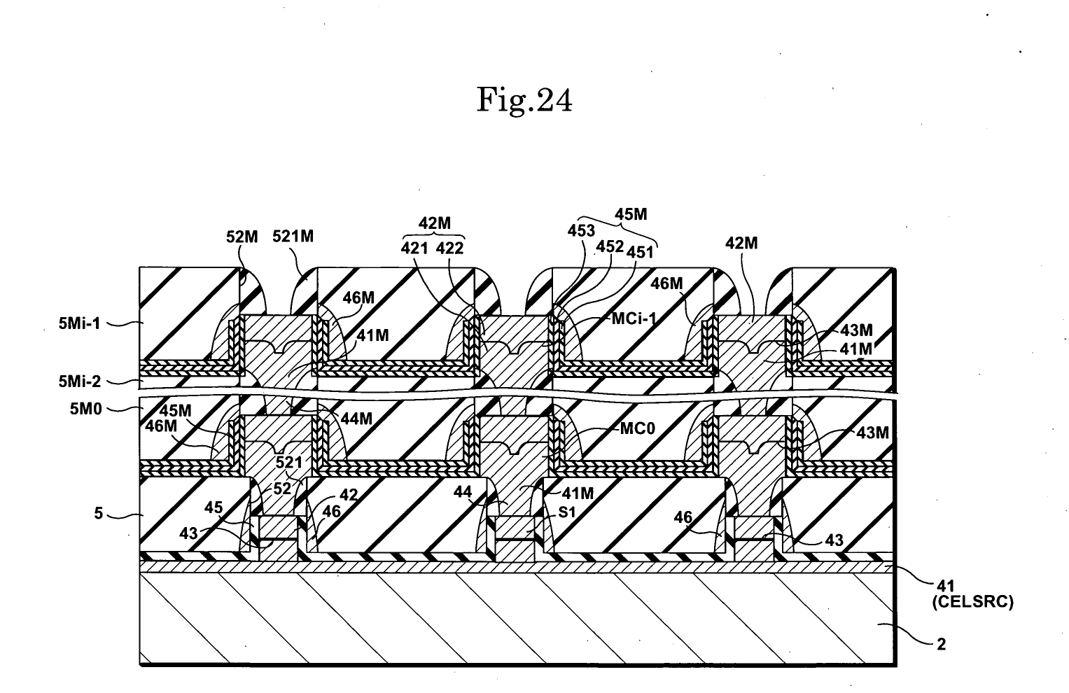

While the second main electrode 44M is laid in the opening 52M which is formed in the interlayer insulation layer 5M0 interposed by the spacer 521M the first semiconductor layer 421 of the first main electrode 41M or the pillar shaped semiconductor layer 42M is formed (See FIG. 24). By forming the second main electrode 44M, the memory cell MC0 is completed in the memory unit MU of the NAND type flash memory 11. Furthermore, because the manufacturing method of the memory cell MC1-memory cell MCi−2 is basically the same as the memory cell MC0, an explanation is omitted here.

The manufacturing method of the memory cell MCi−1 of the highest layer of the memory unit MU us the same as the manufacturing method of the memory cell MC0 and is as follows. Firstly, While the second main electrode 44M of the memory cell MCi−2 is laid in the opening 52M which is formed in the interlayer insulation layer 5Mi−2 interposed by the spacer 521M the first semiconductor layer 421 of the first main electrode 41M or the pillar shaped semiconductor layer 42M of the memory cell MCi−1 is formed (See FIG. 24). Here, by forming the second main electrode 44M, the memory cell MCi−2 which is arranged in the lower layer of this memory cell MC−1 is completed in the memory unit MU of the NAND type flash memory 11. The first semiconductor layer 421 of the first main electrode 41M and the pillar shaped semiconductor layer 42M forms the memory cell MCi−1 which is built in layers on the upper layer of the memory cell MCi−2.

The tunnel insulation layer 43M and the second semiconductor layer 422 are each formed in order on the first semiconductor layer 421 (See FIG. 24). The tunnel insulation layer 43M and the second semiconductor layer 422 form the pillar shaped semiconductor layer 42M. This pillar shaped semiconductor layer 42M is formed in the same way as the pillar shaped semiconductor layer 42M of the memory cell MC0.

Then, the insulation layer 45M is formed around at least the side of the pillar shaped semiconductor layer 42M (See FIG. 24). The insulation layer 45M, is formed from an insulation layer of an ONO construction. The control electrode 46M is formed on the side surface of the pillar shaped semiconductor layer 42M interposed by the insulation layer 45M. The control electrode 46M is formed by self alignment with the pillar shaped semiconductor layer 42M.

The interlayer insulation layer 5Mi−1 which covers the pillar shaped semiconductor layer 42M and the control electrode 46M is formed on the entire surface of the substrate 2 (See FIG. 24). The opening 52M is formed on the pillar shaped semiconductor layer 42M of the interlayer insulation layer 5Mi−1 and, as is shown in FIG. 24, the spacer 521M is formed within this opening 52M.

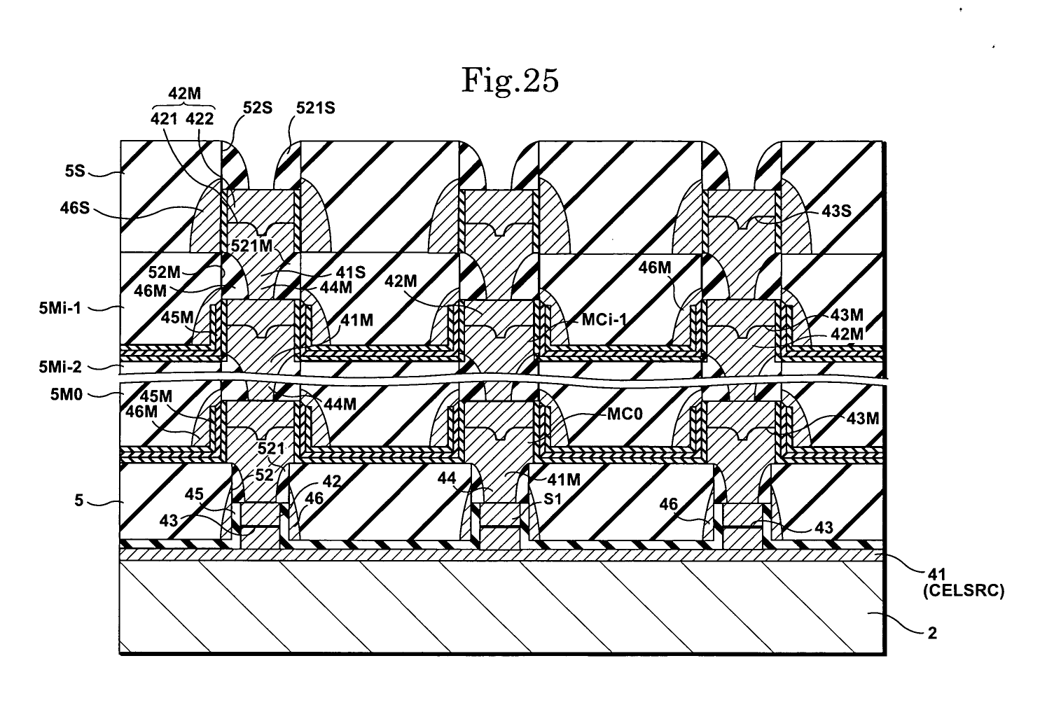

While the second main electrode 44M is laid In the opening 52M which is formed in the interlayer insulation layer 5Mi−1 interposed by the spacer 521M the first main electrode 41S of the second selection transistor S2 and the first semiconductor layer 421 of the pillar shaped semiconductor layer 42M is formed (See FIG. 25). Here, by forming the second main electrode 44S, the memory cell MCi−1 which is arranged on the lower layer of the second selection transistor S2 is completed in the memory unit MU of the NAND type flash memory 11. The first semiconductor layer 421 of the first main electrode 41S and the pillar shaped semiconductor layer 42S forms the second selection transistor which is built in layers on the upper layer of the memory cell MCi−1.

The tunnel insulation layer 43S and the second semiconductor layer 422 are each formed in order on the first semiconductor layer 421 (See FIG. 25). The previously stated first semiconductor layer 421, the tunnel insulation layer 43S and the second semiconductor layer 422 form the pillar shaped semiconductor layer 42S. This pillar shaped semiconductor layer 42S is formed in the same way as the pillar shaped semiconductor layer 42 of the first selection transistor S1.

Then, the insulation layer 45S is formed around at least the side of the pillar shaped semiconductor layer 42S (See FIG. 25). The insulation layer 45S is formed from a silicon oxide layer, for example. The control electrode 46S is formed on the side surface of the pillar shaped semiconductor layer 42S interposed by the insulation layer 45S. The control electrode 46S is formed by self alignment with the pillar shaped semiconductor layer 42S.

The interlayer insulation layer 5S which covers the pillar shaped semiconductor layer 42S and the control electrode 46S is formed on the entire surface of the substrate 2 (See FIG. 25). The opening 52S is formed on the pillar shaped semiconductor layer 42S of the interlayer insulation layer 5S and, as is shown in FIG. 25, the spacer 521S is formed within this opening 52S.

The second main electrode 44S of the second selection transistor S2 is laid in the opening 52S which is formed in the interlayer insulation layer 5S interposed by the spacer 521S (See previously stated FIG. 14 and FIG. 15). When the second main electrode 44s is formed the second selection transistor S2 is completed. As is shown in FIG. 14 and FIG. 15, a wire 6 (data line DL) is formed on the interlayer insulation layer 5S,

The NAND flash memory 11 relating to the third embodiment comprises a tunnel insulation layer 43M on a pillar shaped semiconductor layer 42M of a memory cell MC, a tunnel insulation layer 43 on a pillar shaped semiconductor layer 42 of a first selection transistor S1 and a tunnel insulation layer 43M on a pillar shaped semiconductor layer 42S on a second selection transistor S2. Therefore, when the memory cell MC, the first selection transistor and the second selection transistor are ON, it is possible to sufficiently secure a main current at the time of, for example, a data read operation or a data program operation. Furthermore, because it is possible to prevent an increase in a current leak at the time when the memory cell MC, the first selection transistor and the second selection transistor are OFF during a data read operation it is possible to improve a sense margin. Furthermore, because it is possible to prevent a current leak it is possible to prevent a deterioration of the data retainment characteristics of the memory cell MC.

### Fourth Embodiment

In the fourth embodiment of this invention, an explanation will be given of the transformation examples of the manufacturing method of transistor 4 relating to the previously stated first embodiment, the memory cell 4M relating to the previously stated second embodiment and the memory cell MC or the second selection transistor S2. The manufacturing method of a semiconductor device relating to the fourth embodiment will be explained with the manufacturing method of a semiconductor device relating to the first embodiment as an example.

[Manufacturing Method of a Semiconductor Device]

A manufacturing method of the semiconductor device 1 relating to the fourth embodiment will be explained using FIG. 26 to FIG. 34. Firstly, a substrate 2 is prepared. An isolation area 3 is formed in a non active area on the main surface of this substrate 2 (See FIG. 26). The isolation area 3 is formed by an insulator 32 laid in a trench 31 and an STI construction is adopted in this isolation area 3. As is shown as FIG. 26 the first main electrode 41 is formed in the active area within the area which is surrounded by a non active area. The first main electrode 41 is formed introducing n type impurities using an ion implantation method into the main surface part of the substrate 2 and by activating these n type impurities. Also, it is possible to use a solid phase diffusion method in the introduction of the n type impurities.

As is shown in FIG. 27, an insulation layer 55, an interlayer insulation layer 56, a control electrode 56, an interlayer insulation layer 57 and an insulation layer 58 are respectively formed in order on the entire main surface of the substrate 2. The insulation layer 55 of the lowest layer is used as a barrier layer and a silicon nitride layer which has, for example, a layer thickness of 50 nm, is used in the interlayer insulation layer 55. The control electrode 46 is used a gate electrode of the transistor 4 and is formed by a silicon poly crystal layer or a silicon amorphous layer which has, for example, a layer thickness of 300 nm. N type impurities or p type impurities which control the resistance value are included during or after depositing, in the silicon poly crystal layer. A silicon oxide layer which has a layer thickness of, for example, 50 nm is used in the interlayer insulation layer 57. The insulation layer 58 of the highest layer is used as a cap layer and a silicon nitride layer which has a layer thickness of, for example, 20 nm, is used in this insulation layer 58.

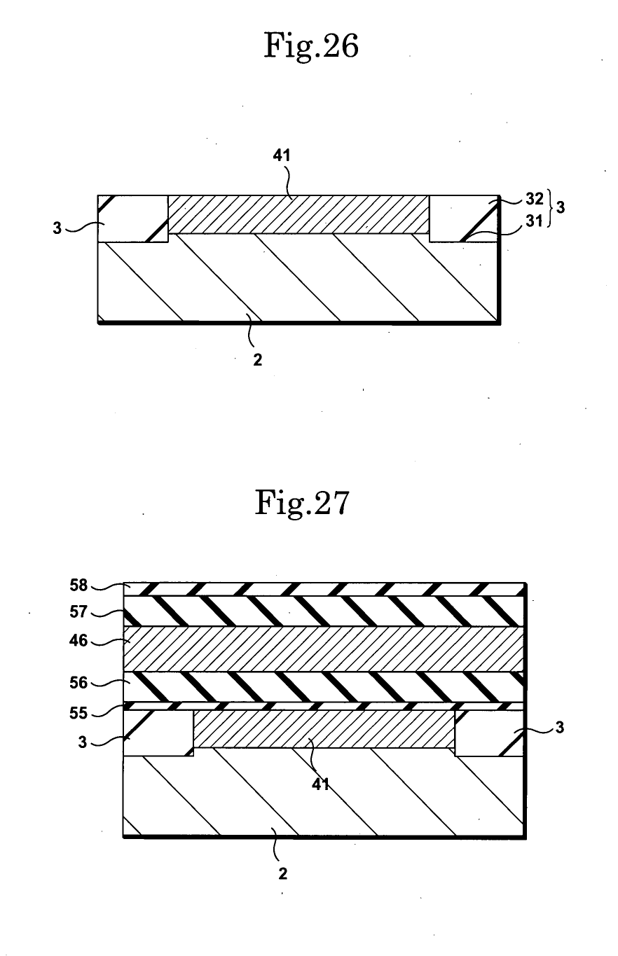

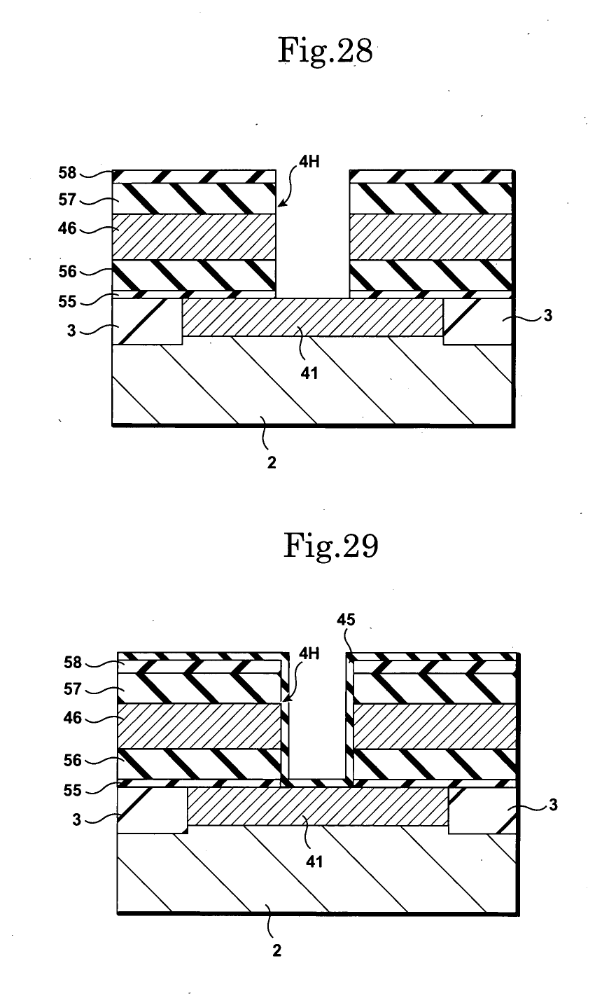

As is shown in FIG. 28, above the active area, that is, above the first main electrode 41, the insulation layer 58 of the highest layer, the interlayer insulation layer 57, the control electrode 46, the interlayer insulation layer 56, and the insulation layer 55 of the lowest layer are each respectively removed and a hole 4H is formed. The hole 4H uses a mask which is formed by photo lithography technology and is formed by removing the insulation layer 58 etc by anisotropic etching such as RIE. This hole 4H is the transistor hole and the main construction components of the transistor 4, that is, the first main electrode, the pillar shaped semiconductor layer, the second main electrode and the tunnel insulation layer are laid in within the hole 4H.

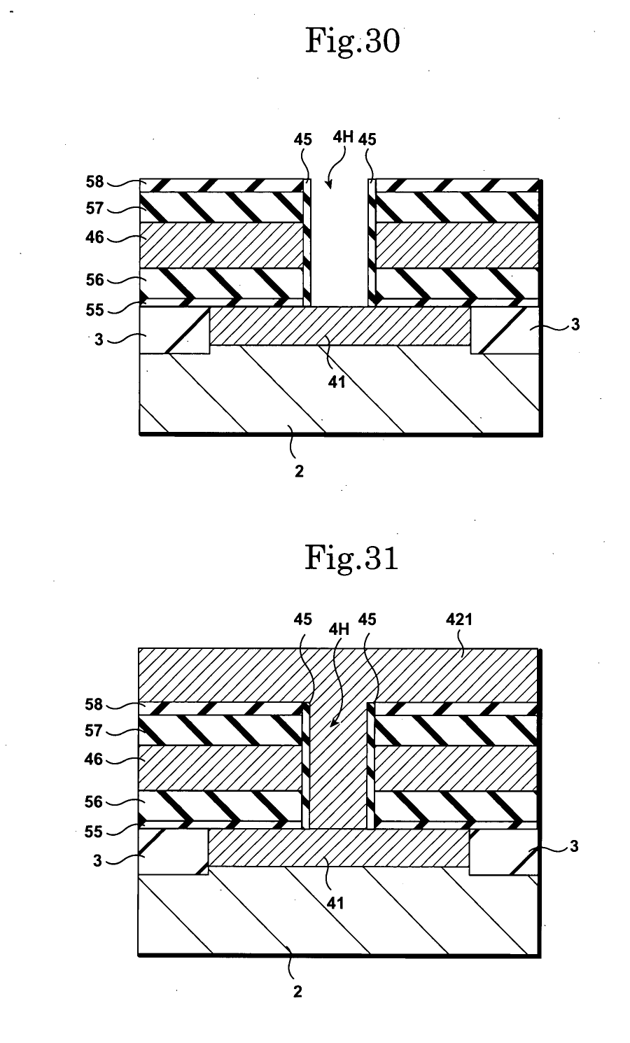

As is shown in FIG. 29, the insulation layer 45 is formed on the inside wall of the hole 4H and in particularly on the surface of the control electrode 46 which is exposed within the hole 4H. The insulation layer 45 is used as a gate insulation layer of the transistor 4 and a silicon oxide layer which has a layer thickness of, for example, 2 nm-15 nm, formed by a CVD method, is used in the insulation layer 45. Also, it is possible to use a silicon nitride layer which has been formed by a silicon oxide layer or nitride method which is formed by oxidization in the insulation layer 45. As is shown in FIG. 30, the insulation layer 58 of the highest layer and the insulation layer 45 above the first main electrode 41 of the bottom surface of the hole 4H is selectively removed and only the insulation layer 45 is left on the inner wall of the hole 4H, that is, left on the said surface within the hole 4H of the control electrode 46. It is possible to use whole surface etching by anisotropic etching such as RIE in the selective removal of the insulation layer 45.

After the surface of the first main electrode 41, which is exposed from within the hole 4H, is cleaned, as is shown in FIG. 31, the first semiconductor layer 421, which is laid inside the hole 4H, is formed above the insulation layer 58. The first semiconductor layer 421, the same as the first semiconductor layer 421 of the previously stated first, second and third embodiments, is formed from a silicon amorphous layer or a silicon poly crystal layer. Here, cleaning is performed with the purpose of removing any natural oxide layers which are produced on the surface of the first main electrode 41 and it is possible to use, for example, dry etching in the cleaning process.

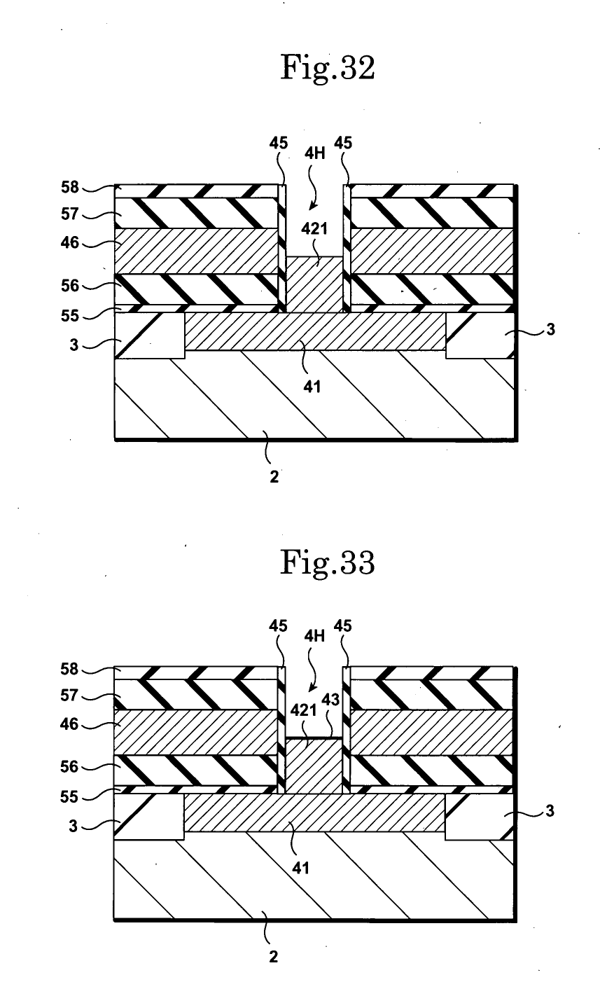

Etching is performed on the entire surface of the first semiconductor layer 421 and, as is shown in FIG. 32, etching is performed until the surface of the first semiconductor layer 421 reaches the central area of the hole 4H, that is, until the surface of the first semiconductor layer 421 reaches a central position between the bottom surface and top surface of the control electrode 46. Here, it is possible to use anisotropic etching such as RIE in the etching process. Here, the first semiconductor layer 421 is used as the pillar shaped semiconductor layer and is used as the first main electrode.

As is shown in FIG. 33, the tunnel insulation 43 is formed on the exposed surface of the first semiconductor layer 421 within the hole 4H. The tunnel insulation layer 43 relating to the fourth embodiment is formed from a silicon oxide layer which oxidizes the surface of the first semiconductor layer 421 in a low temperature and low concentration oxygen atmosphere. The layer thickness of the silicon oxide layer is as previously stated set below 0.6 nm-2.0 nm. In addition, it is possible to use a silicon nitride layer in the tunnel insulation layer 34.

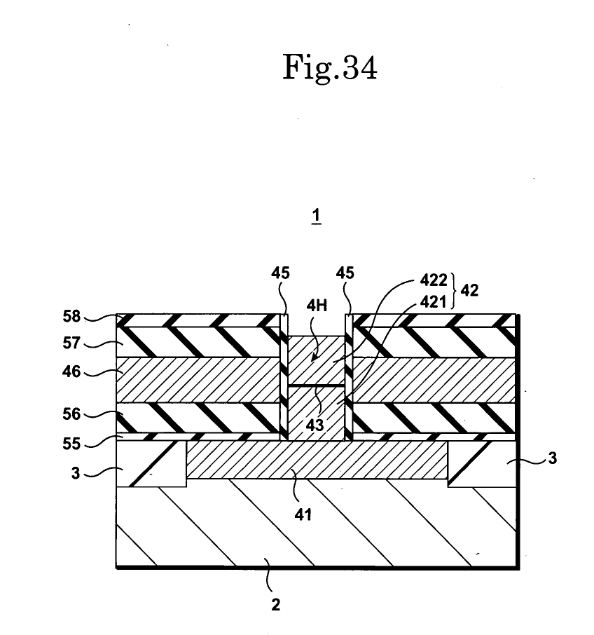

As is shown in FIG. 34, the second semiconductor layer 422 is formed above the tunnel insulation layer 43 within the hole 4H. In the second semiconductor layer 422, the part which is formed further above the upper surface of the control electrode 46 is used as the second main electrode 44. When this second main electrode 44 is formed it is possible to complete the transistor 4 which is arranged with the first main electrode 41 (and one part of the first semiconductor layer 421), the pillar shaped semiconductor layer 42, the second main electrode 44, the insulation layer 45, the control electrode 46 and the tunnel insulation layer 43 which is arranged in the central area of the pillar shaped semiconductor layer 42. And, although not shown in the drawings, by forming a wire etc which is electrically connected to the transistor 4, the semiconductor device 1 of the fourth embodiment can be completed.

Furthermore, it is possible to apply the transistor 4 relating to the fourth embodiment to the memory cell 4M of the NOR type flash memory 10 relating to the second embodiment shown in the previously stated FIG. 10 to FIG. 12. Further, it is possible to apply the transistor 4 relating to the fourth embodiment to the memory cell MC of the NAND type flash memory 11 and both the first selection transistor S1 and the second selection transistor S2 of the third embodiment shown in the previously stated FIG. 14 to FIG. 16.

In the semiconductor device 1 relating to the fourth embodiment, because the pillar shaped semiconductor layer 42 of the transistor 4 is arranged with a tunnel insulation layer 43, the same as the semiconductor device 1 relating to the first embodiment, it is possible to continue to secure a sufficient main current during an ON operation of the transistor 4 and reduce a current leak during a CUT-OFF operation of the transistor 4.

### Fifth Embodiment 5

In the fifth embodiment of this invention, an explanation of a simplified construction will be given while also combining the NAND type flash memory 11 relating to the third embodiment shown in the previously stated FIG. 13 to FIG. 16 and the semiconductor device 1 relating to the fourth embodiment shown in the previously stated FIG. 34.

[Construction of a NAND Flash Memory and Manufacturing Method Thereof]

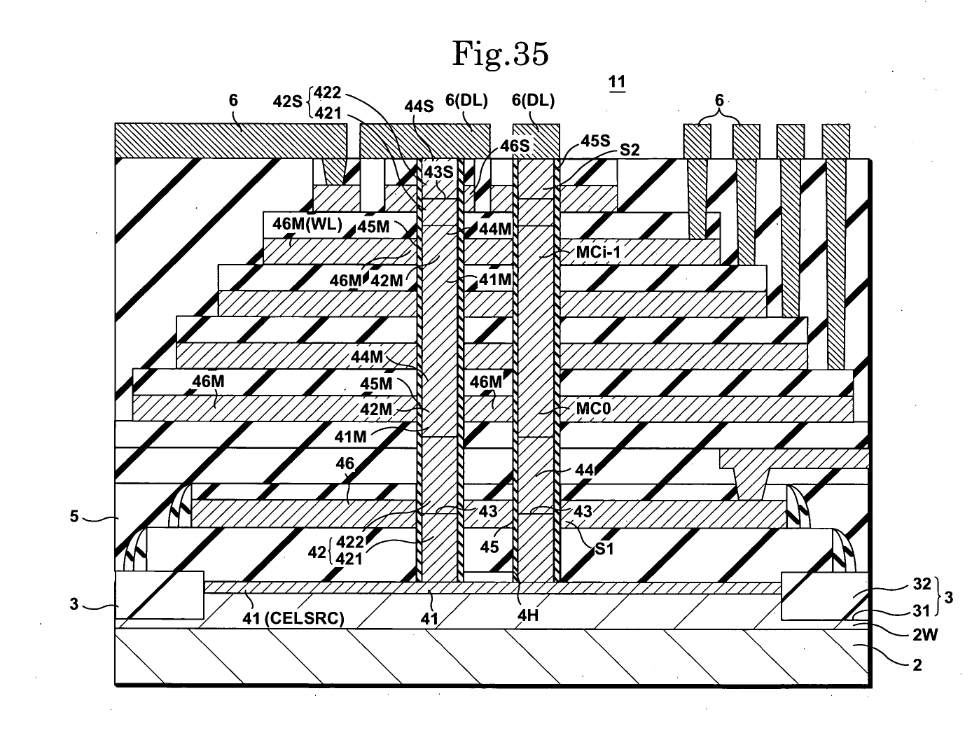

As is shown in FIG. 35, the NAND type flash memory 11 relating to the fifth embodiment, is basically formed by building layers of a first selection transistor S1, a memory cell MC0-memory cell MCi−1 and a second selection transistor S2 on a substrate 2, respectively. A first main electrode 41 of the first selection transistor S1 is used as a source line (SELSRC) (See FIG. 13). A wire 6 is connected to the second selection transistor S2 and the wire 6 is used as a data line (DL). A well region is arranged in the active area on the substrate shown in FIG. 35.

The first selection transistor S1, the memory cell MC0-memory cell MCi−1 and the second selection transistor S2 are all manufactured based on the manufacturing method of the transistor 4 relating to the previously stated fourth embodiment. That is, a hole 4H is formed after a control electrode 46 is formed in the first selection transistor S1, and an insulation layer 45 and a pillar shaped semiconductor layer 42 are formed in this hole 4H. Similarly, a hole 4MH is formed after a the control electrode 46 (and word line WL) is formed in the memory cell MC0-memory cell MCi−1, and the insulation layer 45 and the pillar shaped semiconductor layer 42M are formed in this hole 4MH. A hole 4SH is formed after a control electrode 46S is formed in the second selection transistor S2, and an insulation layer 45S and a pillar shaped semiconductor layer 42S is formed in this hole 4SH.

The NAND flash memory 11 relating to the fifth embodiment is arranged with a tunnel insulation layer 43 in the pillar shaped semiconductor layer 42 of the first selection transistor S1 of a memory string MS and a tunnel insulation layer 43S in a pillar shaped semiconductor layer 42S of a second selection transistor S2. That is, the tunnel insulation layer 43M is not arranged in the pillar shaped semiconductor layer 42M of the memory cell MC0-memory cell MCi−1. Basically, if the flow of current is intersected in the first selection transistor S1 and the second selection transistor S2 a main current leak caused by the pillar shaped semiconductor layer 42M during the CUT-OFF operation of the memory cell MC0-MCi−1 does not occur. Furthermore, in the NAND type flash memory 11 relating to the fifth embodiment, one of either the pillar shaped semiconductor layer 42 of the first selection transistor S1 of the memory string MS or the pillar shaped semiconductor layer 42S of the second selection transistor S2, can be arranged in the tunnel insulation layer 43 or 43S.

### Other Embodiments

This invention is not limited to the previously stated embodiments and within range, various changes are possible which do not deviate from main points. For example, in the previously stated embodiments, an explanation of an example which applied the present invention to a flash memory, was given, however, the present invention can also be applied to a memory device such as a DRAM (dynamic random access memory) or SRAM (static random access memory).

According to one embodiment of the present invention, it is possible to propose a semiconductor device which reduces a leak current at the time of CUT-OFF of a vertical type transistor, a flash memory and their manufacturing methods therein.

What is claimed is:

1. A semiconductor device comprising:
a substrate having a main surface;
a first main electrode formed on the main surface of said substrate;
a pillar shaped semiconductor layer formed on said first main electrode and having poly crystal;
a second main electrode formed on said pillar shaped semiconductor layer;
an insulation layer formed on the side of said pillar shaped semiconductor layer;
a control electrode formed on the side of said pillar shaped semiconductor layer interposed by said insulation layer; and
a tunnel insulation layer which intersects a main current pathway in said pillar shaped semiconductor layer.

2. The semiconductor device in claim 1 wherein said tunnel insulation layer is connected between said first main electrode and said second main electrode and cuts off a grain boundary of said pillar shaped semiconductor layer

3. The semiconductor device in claim 1 wherein said tunnel insulation layer is formed inside said pillar shaped semiconductor layer and the surface of said tunnel insulation layer is made to be horizontally opposed to the main surface of said substrate.

4. The semiconductor device in claim 1 wherein said tunnel insulation layer is formed in the central area between said first main electrode and said second main electrode of said pillar shaped semiconductor layer.

5. The semiconductor device in claim 1 wherein said tunnel insulation layer is a silicon oxide film.

6. The semiconductor device in claim 5 wherein the layer thickness of said tunnel insulation layer is less than 2 nm.

7. The semiconductor device in claim 1 wherein said first main electrode, said second main electrode, said pillar shaped semiconductor layer and said insulation layer and said control electrode are comprised of an insulating gate type field-effect transistor.

8. The semiconductor device in claim 7 wherein said tunnel insulation layer intersects a channel region which is produced in said pillar shaped semiconductor layer of said insulating gate type field-effect transistor, passes a main electric current through the channel region in operation state and cuts off a leak current which flows in the channel region in non-operation state.

9. The semiconductor device in claim 1 wherein one or a plurality of said tunnel insulation layers is formed between said main first electrode and said second main electrode in said pillar shaped semiconductor layer.

10. The semiconductor device in claim 1 wherein said insulation layer has a charge accumulating region.

11. The semiconductor device in claim 1 wherein said insulation layer comprises a first insulation layer formed on the side of said pillar shaped semiconductor layer, a second insulation layer of a different material to said first insulation layer formed on said first insulation layer and a third insulation layer of the same material as said first insulation layer formed on said second insulation layer.

12. A semiconductor device comprising:
a substrate having a main surface;
a first main electrode formed on the main surface of the substrate;
a first pillar shaped semiconductor layer formed on the first main electrode and having poly crystal;
a second main electrode formed on the first pillar shaped semiconductor layer;
a first insulation layer formed on the side of the first pillar shaped semiconductor layer and;
a first transistor having a first control electrode formed on the side of the first pillar shaped semiconductor layer interposed by the first insulation layer;
a third main electrode formed on the first transistor;
a second pillar shaped semiconductor formed on the third main electrode and having poly crystal;
a fourth main electrode formed on the second pillar shaped semiconductor;
a second insulation layer formed on the side of the second pillar shaped semiconductor and having a electric charge stack layer and;
a second transistor having a second control electrode formed on the side of the second pillar shaped semiconductor layer interposed by the second insulation layer;
a fifth main electrode formed on the second transistor;
a third pillar shaped semiconductor layer formed on the fifth main electrode and having poly crystal;
a sixth main electrode formed on the third pillar shaped semiconductor layer;
a third insulation layer formed on the side of the third pillar shaped semiconductor layer and;
a third transistor having a third control electrode formed on the side of the third pillar shaped semiconductor layer interposed by the third insulation layer and;
a tunnel insulation layer which intersects a main current pathway in either a first pillar shaped semiconductor of a first transistor, a second pillar shaped semiconductor of a second transistor or a third pillar shaped semiconductor of a third transistor.

13. The semiconductor device in claim 12 wherein said second transistor is a nonvolatile memory cell and a plurality of said second transistors are arranged and electrically connected in series.

14. The semiconductor device in claim 13 wherein said plurality of second transistors which are electrically connected in series include a memory string, said first transistor and said second transistor include a selection transistor which performs selection as well as un-selection of said memory string and said memory string and said selection transistor construct a NAND type flash memory.

15. The semiconductor device in claim 12 wherein said tunnel insulation layer is arranged only on the third pillar shaped semiconductor layer of said third transistor.

16. A method of manufacturing a semiconductor device comprising:
forming a first main electrode on the main surface of a substrate;
forming one part of a pillar shaped semiconductor layer on said first main electrode;
forming a tunnel insulation layer on the surface of one part of said pillar shaped semiconductor layer;
forming another one part of said pillar shaped semiconductor layer on said tunnel insulation layer and forming said pillar shaped semiconductor layer interposed by said one part and said other one part and having poly crystal;
forming an insulation layer on the side of said pillar shaped semiconductor layer and;
forming a control electrode on the side of said pillar shaped semiconductor interposed by said insulation layer.

17. The method of the claim 16 wherein an insulation layer is formed on the side of said pillar shaped semiconductor layer after forming said pillar shaped semiconductor layer and after that forming said control electrode on said insulation layer.

18. The method of the claim 16 wherein said insulation layer is formed on the side of said control electrode after forming said control electrode and after that forming said pillar shaped semiconductor layer on said insulation layer.

19. The method of the claim 16 wherein one part and another part of said pillar shaped semiconductor layer are layer formed from an amorphous substance and are poly-crystallized as a final crystal construction.

20. The method of the claim 16 wherein said first main electrode, said pillar shaped semiconductor, said second main electrode, said insulation layer and said control electrode form a selection transistor which selects as well as deselects a nonvolatile memory cell or said nonvolatile memory cell.
